(19) United States
(12) Patent Application Publication
(10) Pub. No.: US 2003/0015704 A1
(43) Pub. Date: Jan. 23, 2003

(54) Structure and process for fabricating semiconductor structures and devices utilizing the formation of a compliant substrate for materials used to form the same including intermediate surface cleaning

(75) Inventor: Jay A. Curless, Phoenix, AZ (US)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: MOTOROLA, INC., Schaumburg, IL (US)

(21) Appl. No.: 09/910,023

(22) Filed: Jul. 23, 2001

(51) Int. Cl. H01L 27/108; H01L 29/04; H01L 29/76; H01L 31/036; H01L 21/00; H01L 21/469; H01L 21/31

(52) U.S. Cl. 257/69; 257/201; 257/200; 438/3; 438/778; 438/761

(57) ABSTRACT

Process for fabrication of semiconductor structures and devices (267, 270) including an intermediate surface cleaning procedure performed to remove metal contaminants in the surface region (262) of a seed film (261) of a monocrystalline compound semiconductor material that is formed overlying a perovskite oxide film (24), which is the source of the contaminants. After removal of the contaminated surface region (262), monocrystalline compound semiconductor material is regrown on the remaining seed film (264) to form a layer (266) having a thickness suitable for forming devices therein.

### FIELD OF THE INVENTION

This invention relates generally to fabrication of semiconductor structures and devices, and, more specifically, to processes for fabricating semiconductor structures including an intermediate surface cleaning procedure performed after a seed film of a monocrystalline compound semiconductor material is formed on a semiconductor structure, and before deposition of the monocrystalline compound semiconductor material in a greater thickness such as that suitable for device fabrication therein.

### BACKGROUND OF THE INVENTION

Semiconductor devices often include multiple layers of conductive, insulating, and semiconductive layers. Often, the desirable properties of such layers improve with the crystallinity of the layer. For example, the electron mobility and band gap of semiconductive layers improves as the crystallinity of the layer increases. Similarly, the free electron concentration of conductive layers and the electron charge displacement and electron energy recoverability of insulative or dielectric films improves as the crystallinity of these layers increases.

For many years, attempts have been made to grow various monolithic thin films on a foreign substrate such as silicon (Si). To achieve optimal characteristics of the various monolithic layers, however, a monocrystalline film of high crystalline quality is desired. Attempts have been made, for example, to grow various monocrystalline layers on a substrate such as germanium, silicon, and various insulators. These attempts have generally been unsuccessful because lattice mismatches between the host crystal and the grown crystal have caused the resulting layer of monocrystalline material to be of low crystalline quality.

If a large area thin film of high quality monocrystalline material was available at low cost, a variety of semiconductor devices could advantageously be fabricated in or using that film at a low cost compared to the cost of fabricating such devices beginning with a bulk wafer of semiconductor material or in an epitaxial film of such material on a bulk wafer of semiconductor material. In addition, if a thin film of high quality monocrystalline material could be realized beginning with a bulk wafer such as a silicon wafer, an integrated device structure could be achieved that took advantage of the best properties of both the silicon and the high quality monocrystalline material.

Accordingly, a need exists for a semiconductor structure that provides a high quality monocrystalline film or layer over another monocrystalline material and for a process for making such a structure. In other words, there is a need for providing the formation of a monocrystalline substrate that is compliant with a high quality monocrystalline material layer so that true two-dimensional growth can be achieved for the formation of quality semiconductor structures, devices and integrated circuits having grown monocrystalline film having the same crystal orientation as an underlying substrate. This monocrystalline material layer may be comprised of a semiconductor material, a compound semiconductor material, and other types of material such as metals and non-metals. There also exists a need for fabrication techniques in such structures that minimize or prevent inter-layer contamination of the high quality monocrystalline layer due to possible diffusion of constituents from adjoining layers, yet in a manner compatible with the compliant structure needed.

### BRIEF DESCRIPTION OF THE DRAWINGS

The present invention is illustrated by way of example and not limitation in the accompanying figures, in which like references indicate similar elements, and in which:

FIGS. 1, 2, and 3 illustrate schematically, in cross section, device structures in accordance with various embodiments of the invention;

FIG. 4 illustrates graphically the relationship between maximum attainable film thickness and lattice mismatch between a host crystal and a grown crystalline overlayer;

FIG. 5 illustrates a high resolution Transmission Electron Micrograph of a structure including a monocrystalline accommodating buffer layer;

FIG. 6 illustrates an x-ray diffraction spectrum of a structure including a monocrystalline accommodating buffer layer;

FIG. 7 illustrates a high resolution Transmission Electron Micrograph of a structure including an amorphous oxide layer;

FIG. 8 illustrates an x-ray diffraction spectrum of a structure including an amorphous oxide layer;

FIGS. 9-12 illustrate schematically, in cross-section, the formation of a device structure in accordance with another embodiment of the invention;

FIGS. 13-16 illustrate a probable molecular bonding structure of the device structures illustrated in FIGS. 9-12;

FIGS. 17-20 illustrate schematically, in cross-section, the formation of a device structure in accordance with still another embodiment of the invention; and

FIGS. 24-27 illustrate schematically, in cross section, the formation of a device structure in accordance with another embodiment of the invention;

FIG. 28 illustrates a flow chart of a process for fabricating the device structure shown in FIG. 27.

FIGS. 29-31 illustrate schematically, in cross section, the formation of a device structure in accordance with another embodiment of the invention; and

FIG. 32 illustrates a flow chart of a process for fabricating the device structure shown in FIG. 31.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

### DETAILED DESCRIPTION OF THE DRAWINGS

FIG. 1 illustrates schematically, in cross section, a portion of a semiconductor structure 20 in accordance with an embodiment of the invention. Semiconductor structure 20 includes a monocrystalline substrate 22, accommodating buffer layer 24 comprising a monocrystalline material, and a monocrystalline material layer 26. In this context, the term “monocrystalline” shall have the meaning commonly used within the semiconductor industry. The term shall refer to materials that are a single crystal or that are substantially a single crystal and shall include those materials having a relatively small number of defects such as dislocations and the like as are commonly found in substrates of silicon or germanium or mixtures of silicon and germanium and epitaxial layers of such materials commonly found in the semiconductor industry.

In accordance with one embodiment of the invention, structure 20 also includes an amorphous intermediate layer 28 positioned between substrate 22 and accommodating buffer layer 24. Structure 20 may also include a template layer 30 between the accommodating buffer layer and monocrystalline material layer 26. As will be explained more fully below, the template layer helps to initiate the growth of the monocrystalline material layer on the accommodating buffer layer. The amorphous intermediate layer helps to relieve the strain in the accommodating buffer layer and by doing so, aids in the growth of a high crystalline quality accommodating buffer layer.

Substrate 22, in accordance with an embodiment of the invention, is a monocrystalline semiconductor or compound semiconductor wafer, preferably of large diameter. The wafer can be of, for example, a material from Group IV of the periodic table. Examples of Group IV semiconductor materials include silicon, germanium, mixed silicon and germanium, mixed silicon and carbon, mixed silicon, germanium and carbon, and the like. Preferably substrate 22 is a wafer containing silicon or germanium, and most preferably is a high quality monocrystalline silicon wafer as used in the semiconductor industry. Accommodating buffer layer 24 is preferably a monocrystalline oxide or nitride material epitaxially grown on the underlying substrate. In accordance with one embodiment of the invention, amorphous intermediate layer 28 is grown on substrate 22 at the interface between substrate 22 and the growing accommodating buffer layer by the oxidation of substrate 22 during the growth of layer 24. The amorphous intermediate layer serves to relieve strain that might otherwise occur in the monocrystalline accommodating buffer layer as a result of differences in the lattice constants of the substrate and the buffer layer. As used herein, lattice constant refers to the distance between atoms of a cell measured in the plane of the surface. If such strain is not relieved by the amorphous intermediate layer, the strain may cause defects in the crystalline structure of the accommodating buffer layer. Defects in the crystalline structure of the accommodating buffer layer, in turn, would make it difficult to achieve a high quality crystalline structure in monocrystalline material layer 26 which may comprise a semiconductor material, a compound semiconductor material, or another type of material such as a metal or a non-metal.

Accommodating buffer layer 24 is preferably a monocrystalline oxide or nitride material selected for its crystalline compatibility with the underlying substrate and with the overlying material layer. For example, the material could be an oxide or nitride having a lattice structure closely matched to the substrate and to the subsequently applied monocrystalline material layer. Materials that are suitable for the accommodating buffer layer include metal oxides such as the alkaline earth metal titanates, alkaline earth metal zirconates, alkaline earth metal hafnates, alkaline earth metal tantalates, alkaline earth metal ruthenates, alkaline earth metal niobates, alkaline earth metal vanadates, alkaline earth metal tin-based perovskites, lanthanum aluminate, lanthanum scandium oxide, and gadolinium oxide. Additionally, various nitrides such as gallium nitride, aluminum nitride, and boron nitride may also be used for the accommodating buffer layer. Most of these materials are insulators, although strontium ruthenate, for example, is a conductor. Generally, these materials are metal oxides or metal nitrides, and more particularly, these metal oxide or nitrides typically include at least two different metallic elements. In some specific applications, the metal oxides or nitrides may include three or more different metallic elements.

Amorphous interface layer 28 is preferably an oxide formed by the oxidation of the surface of substrate 22, and more preferably is composed of a silicon oxide. The thickness of layer 28 is sufficient to relieve strain attributed to mismatches between the lattice constants of substrate 22 and accommodating buffer layer 24. Typically, layer 28 has a thickness in the range of approximately 0.5-5 nm.

The material for monocrystalline material layer 26 can be selected, as desired, for a particular structure or application. For example, the monocrystalline material of layer 26 may comprise a compound semiconductor which can be selected, as needed for a particular semiconductor structure, from any of the Group IIIA and VA elements (III-V semiconductor compounds), mixed III-V compounds, Group II(A or B) and VIA elements (II-VI semiconductor compounds), and mixed II-VI compounds. Examples include gallium arsenide (GaAs), gallium indium arsenide (GaInAs), gallium aluminum arsenide (GaAlAs), indium phosphide (InP), cadmium sulfide (CdS), cadmium mercury telluride (CdHgTe), zinc selenide (ZnSe), zinc sulfur selenide (ZnSSe), and the like. However, monocrystalline material layer 26 may also comprise other semiconductor materials, metals, or non-metal materials which are used in the formation of semiconductor structures, devices and/or integrated circuits.

Appropriate materials for template 30 are discussed below. Suitable template materials chemically bond to the surface of the accommodating buffer layer 24 at selected sites and provide sites for the nucleation of the epitaxial growth of monocrystalline material layer 26. When used, template layer 30 has a thickness ranging from about 1 to about 10 monolayers.

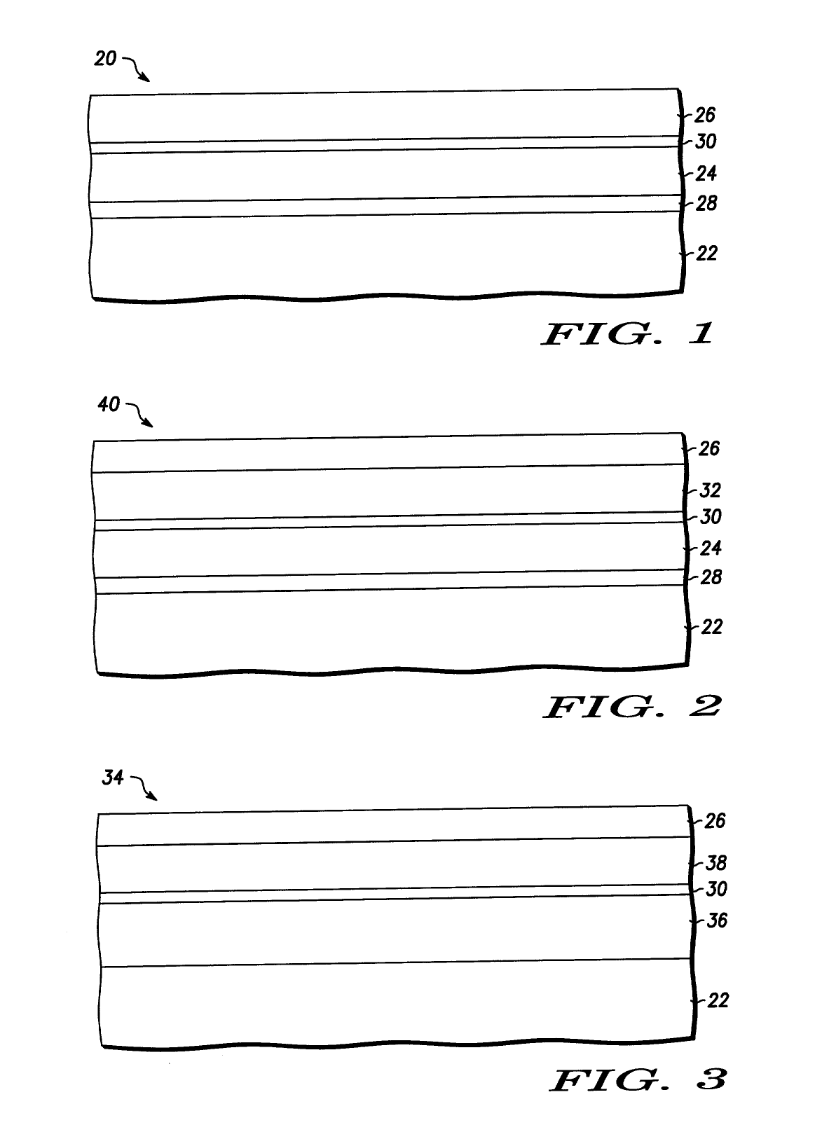

FIG. 2 illustrates, in cross section, a portion of a semiconductor structure 40 in accordance with a further embodiment of the invention. Structure 40 is similar to the previously described semiconductor structure 20, except that an additional buffer layer 32 is positioned between accommodating buffer layer 24 and monocrystalline material layer 26. Specifically, the additional buffer layer is positioned between template layer 30 and the overlying layer of monocrystalline material. The additional buffer layer, formed of a semiconductor or compound semiconductor material when the monocrystalline material layer 26 comprises a semiconductor or compound semiconductor material, serves to provide a lattice compensation when the lattice constant of the accommodating buffer layer cannot be adequately matched to the overlying monocrystalline semiconductor or compound semiconductor material layer.

FIG. 3 schematically illustrates, in cross section, a portion of a semiconductor structure 34 in accordance with another exemplary embodiment of the invention. Structure 34 is similar to structure 20, except that structure 34 includes an amorphous layer 36, rather than accommodating buffer layer 24 and amorphous interface layer 28, and an additional monocrystalline layer 38.

As explained in greater detail below, amorphous layer 36 may be formed by first forming an accommodating buffer layer and an amorphous interface layer in a similar manner to that described above. Monocrystalline layer 38 is then formed (by epitaxial growth) overlying the monocrystalline accommodating buffer layer. The accommodating buffer layer is then exposed to an anneal process to convert the monocrystalline accommodating buffer layer to an amorphous layer. Amorphous layer 36 formed in this manner comprises materials from both the accommodating buffer and interface layers, which amorphous layers may or may not amalgamate. Thus, layer 36 may comprise one or two amorphous layers. Formation of amorphous layer 36 between substrate 22 and additional monocrystalline layer 26 (subsequent to layer 38 formation) relieves stresses between layers 22 and 38 and provides a true compliant substrate for subsequent processing—e.g., monocrystalline material layer 26 formation.

The processes previously described above in connection with FIGS. 1 and 2 are adequate for growing monocrystalline material layers over a monocrystalline substrate. However, the process described in connection with FIG. 3, which includes transforming a monocrystalline accommodating buffer layer to an amorphous oxide layer, may be better for growing monocrystalline material layers because it allows any strain in layer 26 to relax.

Additional monocrystalline layer 38 may include any of the materials described throughout this application in connection with either of monocrystalline material layer 26 or additional buffer layer 32. For example, when monocrystalline material layer 26 comprises a semiconductor or compound semiconductor material, layer 38 may include monocrystalline Group IV or monocrystalline compound semiconductor materials.

In accordance with one embodiment of the present invention, additional monocrystalline layer 38 serves as an anneal cap during layer 36 formation and as a template for subsequent monocrystalline layer 26 formation. Accordingly, layer 38 is preferably thick enough to provide a suitable template for layer 26 growth (at least one monolayer) and thin enough to allow layer 38 to form as a substantially defect free monocrystalline material.

In accordance with another embodiment of the invention, additional monocrystalline layer 38 comprises monocrystalline material (e.g., a material discussed above in connection with monocrystalline layer 26) that is thick enough to form devices within layer 38. In this case, a semiconductor structure in accordance with the present invention does not include monocrystalline material layer 26. In other words, the semiconductor structure in accordance with this embodiment only includes one monocrystalline layer disposed above amorphous oxide layer 36.

Referring now to FIG. 27, and as another embodiment of the invention, a unique process is set forth for fabricating semiconductor device structure 267 having reduced incidence of foreign metal contamination in the monocrystalline compound semiconductor device layer 266, which is compliantly attached to a monocrystalline semiconductor substrate 22 via an amorphous oxide layer 28, a perovskite oxide film 24, a capping/template layer 30, and a monocrystalline compound semiconductor seed film 264, in that order from furthest to closest to layer 266.

Referring to FIG. 1 for sake of illustration here, certain metal components of the perovskite oxide film 24, for example, such as strontium (Sr), titanium (Ti) and/or barium (Ba) atomic species, have a tendency to surface segregate onto the surface of perovskite oxide film 24, and then rise with the crystal growth surface of the overlying layers that are epitaxially formed thereon. These metal components remaining on the crystal growth surface can contaminate neighboring layers, such as the monocrystalline compound semiconductor layer 26, when they are grown over perovskite oxide film 24. This phenomenon has been confirmed by observations made by secondary ion mass spectroscopy (SIMS) which confirm the presence of atomic metal constituents, such as Sr and Ti, of the types in the perovskite oxide film, such as SrTiO₃, on the surface of the overlying compound semiconductor layer 26, such as GaAs. This contamination can take the form of a concentration of the metal component contaminants, which originate from perovskite oxide film 24, at the surface region of compound semiconductor layer 26, as well as some amount of contamination in the bulk or interior of the overlying compound semiconductor layer 26.

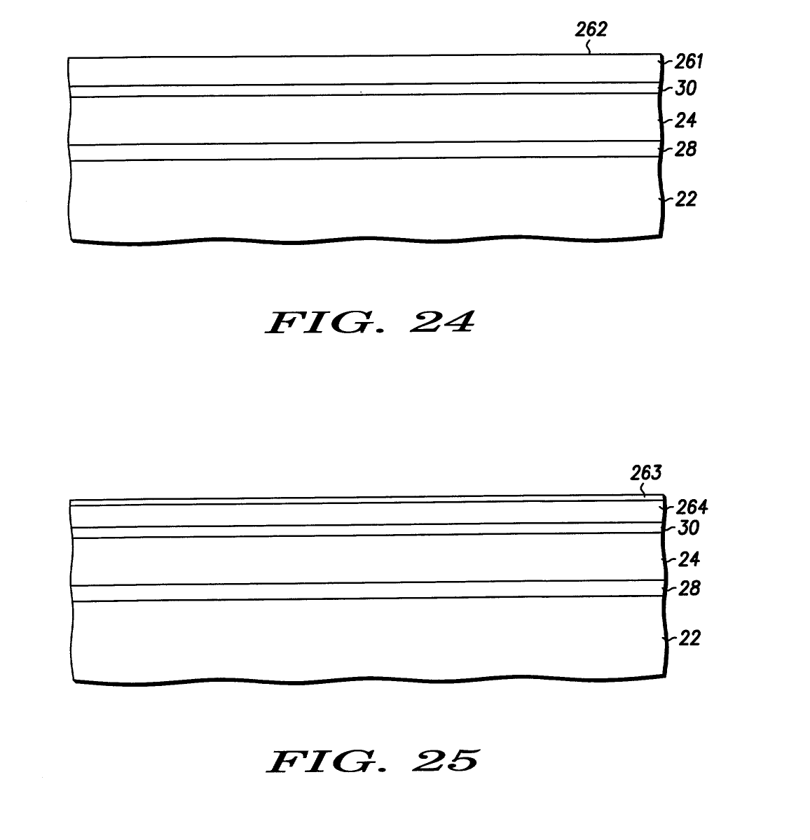

The presence of such contaminant metal atoms originating in the perovskite oxide film 24 in or on the overlying high quality compound semiconductor 26 is undesirable. This contamination can undesirably alter the electrical and/or optical properties of high quality compound semiconductor device layer 26, which, in turn, could adversely affect device performance. For instance, when Sr, Ti and/or Ba and the like metal components of a perovskite oxide film 24 segregate and accumulate on the surface of the overlying compound semiconductor layer 26, they can cause an unusually large zero bias depletion region (i.e., cause a lowering of capacitance), which occurs ostensibly through pinning of the Fermi level. As a result, for example, it becomes difficult to form a Schottky barrier. In addition, while the Sr, Ti and/or Ba and the like contaminants prefer to be on the surface of the compound semiconductor layer 26, some act to dope further growth and can become incorporated into the bulk of the compound semiconductor layer 26 as it is grown to its complete thickness. These contaminant-dopants present in the bulk of the compound semiconductor layer 26 can lower carrier mobility and provide recombination centers, which are non-radiative. The embodiments of the invention such as shown in FIGS. 24-32, alleviate this possible problem by interposing a unique surface cleaning procedure to significantly reduce the presence of the aforesaid contaminants.

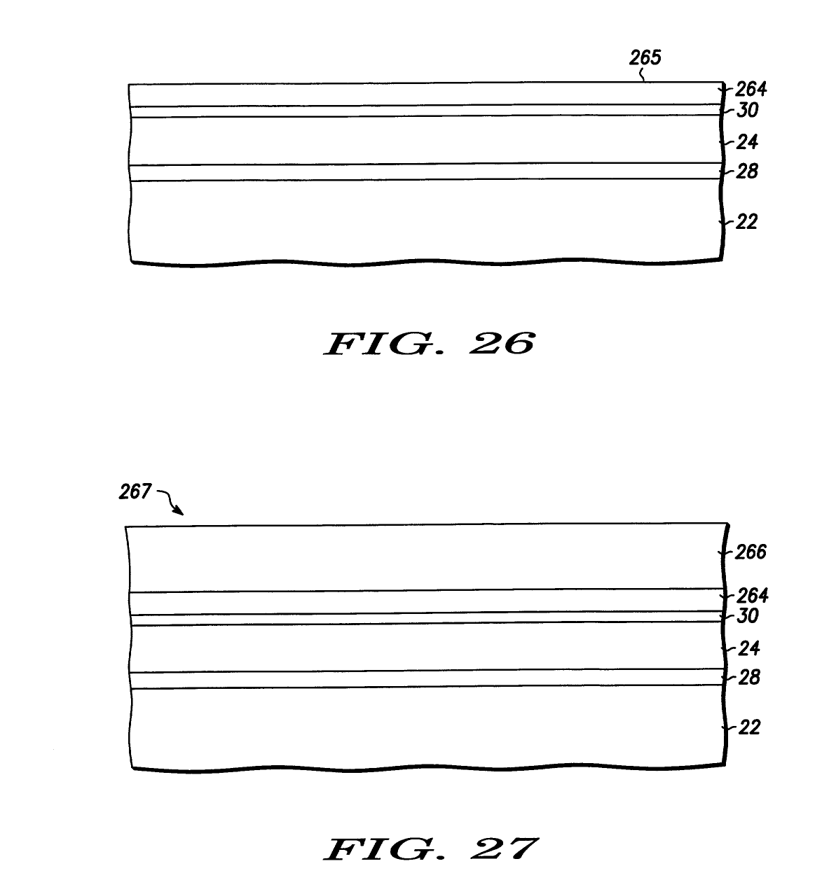

Generally, the present invention significantly reduces the risk of this contamination problem by initially growing a compound semiconductor seed film 261 on template 30 (FIG. 24), before forming a compound semiconductor layer thereon having a predetermined thickness suitable for formation of devices therein. In the illustration shown in FIG. 24, the compound semiconductor seed film 261, as originally formed, includes an original upper surface 262 contaminated with metal atoms that have surface segregated from perovskite oxide film 24 and which have risen with the growth surface during formation of the overlying compound semiconductor film 261. The contaminated surface region 262 of the compound semiconductor seed film 261 is then removed (e.g., see FIG. 26), while leaving an underlying portion of compound semiconductor seed film 264, which has significantly reduced metal contamination at its surface 265 as compared to the original surface 262. In addition, surface 265 is available as a growth site for forming thicker monocrystalline compound semiconductor layer 266 (e.g., see FIG. 27).

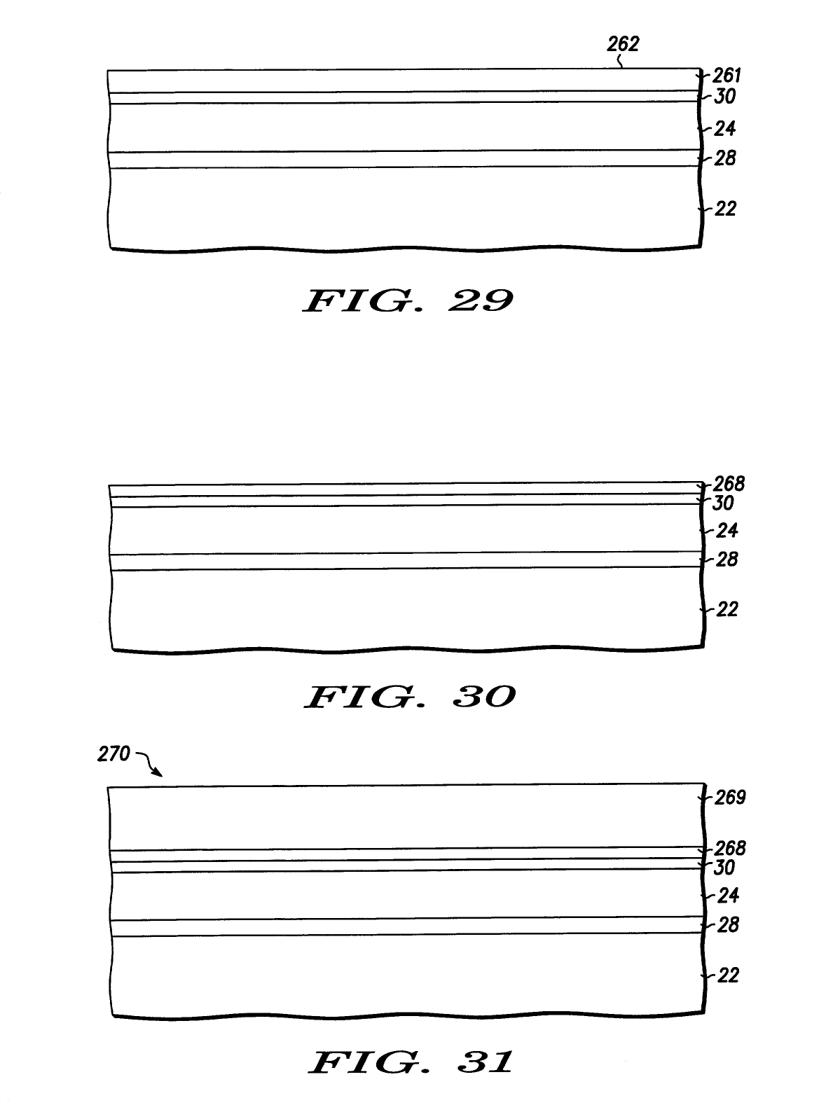

As will be explained in greater detail below in the examples, this removal can be effected according to this invention by surface oxidation and desorption (FIGS. 25-26), or alternatively, by an etch back procedure (FIGS. 29-30). As shown in FIG. 27, for example, a thicker monocrystalline compound semiconductor layer 266 is then grown on the newly exposed surface 265 of the remaining compound semiconductor seed film 264. As a consequence of removing the contaminated surface region 262 of the monocrystalline compound semiconductor seed film 261 before formation of thicker monocrystalline compound semiconductor layer 266, contamination of compound semiconductor layer 266 by metal atoms that had surface segregated from perovskite oxide film 24 is significantly reduced or even substantially eliminated. For example, at least a majority (i.e., greater than 50% of the original amount), as well as higher percentages such as greater than 90% or higher or even essentially all, of the metal contaminants can be removed from the contaminated surface region in this manner.

The following non-limiting, illustrative examples illustrate various combinations of materials useful in structures 20, 40, and 34 in accordance with various alternative embodiments of the invention. These examples are merely illustrative, and it is not intended that the invention be limited to these illustrative examples.

### EXAMPLE 1

In accordance with one embodiment of the invention, monocrystalline substrate 22 is a silicon substrate oriented in the (100) direction. The silicon substrate can be, for example, a silicon substrate as is commonly used in making complementary metal oxide semiconductor (CMOS) integrated circuits having a diameter of about 200-300 mm. In accordance with this embodiment of the invention, accommodating buffer layer 24 is a monocrystalline layer of Sr_{z}Ba_{1-z}TiO₃ where z ranges from 0 to 1 and the amorphous intermediate layer is a layer of silicon oxide (SiOₓ) formed at the interface between the silicon substrate and the accommodating buffer layer. The value of z is selected to obtain one or more lattice constants closely matched to corresponding lattice constants of the subsequently formed layer 26. The accommodating buffer layer can have a thickness of about 2 to about 100 nanometers (nm) and preferably has a thickness of about 5 nm. In general, it is desired to have an accommodating buffer layer thick enough to isolate the monocrystalline material layer 26 from the substrate to obtain the desired electrical and optical properties. Layers thicker than 100 nm usually provide little additional benefit while increasing cost unnecessarily; however, thicker layers may be fabricated if needed. The amorphous intermediate layer of silicon oxide can have a thickness of about 0.5-5 nm, and preferably a thickness of about 1 to 2 nm.

In accordance with this embodiment of the invention, monocrystalline material layer 26 is a compound semiconductor layer of gallium arsenide (GaAs) or aluminum gallium arsenide (AlGaAs) having a thickness of about 1 nm to about 100 micrometers (μm) and preferably a thickness of about 0.5 μm to 10 μm. The thickness generally depends on the application for which the layer is being prepared. To facilitate the epitaxial growth of the gallium arsenide or aluminum gallium arsenide on the monocrystalline oxide, a template layer is formed by capping the oxide layer. The template layer is preferably 1-10 monolayers of Ti—As, Sr—O—As, Sr—Ga—O, or Sr—Al—O. By way of a preferred example, 1-2 monolayers of Ti—As or Sr—Ga—O have been illustrated to successfully grow GaAs layers.

### EXAMPLE 2

In accordance with a further embodiment of the invention, monocrystalline substrate 22 is a silicon substrate as described above. The accommodating buffer layer is a monocrystalline oxide of strontium or barium zirconate or hafnate in a cubic or orthorhombic phase with an amorphous intermediate layer of silicon oxide formed at the interface between the silicon substrate and the accommodating buffer layer. The accommodating buffer layer can have a thickness of about 2-100 nm and preferably has a thickness of at least 5 nm to ensure adequate crystalline and surface quality and is formed of a monocrystalline SrZrO₃, BaZrO₃, SrHfO₃, BaSnO₃ or BaHfO₃. For example, a monocrystalline oxide layer of BaZrO₃ can grow at a temperature of about 700° C. The lattice structure of the resulting crystalline oxide exhibits a 45 degree rotation with respect to the substrate silicon lattice structure.

An accommodating buffer layer formed of these zirconate or hafnate materials is suitable for the growth of a monocrystalline material layer which comprises compound semiconductor materials in the indium phosphide (InP) system. In this system, the compound semiconductor material can be, for example, indium phosphide (InP), indium gallium arsenide (InGaAs), aluminum indium arsenide, (AlInAs), or aluminum gallium indium arsenic phosphide (AlGaInAsP), having a thickness of about 1.0 nm to 10 μm. A suitable template for this structure is 1-10 monolayers of zirconium-arsenic (Zr—As), zirconium-phosphorus (Zr—P), hafnium-arsenic (Hf—As), hafnium-phosphorus (Hf—P), strontium-oxygen-arsenic (Sr—O—As), strontium-oxygen-phosphorus (Sr—O—P), barium-oxygen-arsenic (Ba—O—As), indium-strontium-oxygen (In—Sr—O), or barium-oxygen-phosphorus (Ba—O—P), and preferably 1-2 monolayers of one of these materials. By way of an example, for a barium zirconate accommodating buffer layer, the surface is terminated with 1-2 monolayers of zirconium followed by deposition of 1-2 monolayers of arsenic to form a Zr-As template. A monocrystalline layer of the compound semiconductor material from the indium phosphide system is then grown on the template layer. The resulting lattice structure of the compound semiconductor material exhibits a 45 degree rotation with respect to the accommodating buffer layer lattice structure and a lattice mismatch to (100) InP of less than 2.5%, and preferably less than about 1.0%.

### EXAMPLE 3

In accordance with a further embodiment of the invention, a structure is provided that is suitable for the growth of an epitaxial film of a monocrystalline material comprising a II-VI material overlying a silicon substrate. The substrate is preferably a silicon wafer as described above. A suitable accommodating buffer layer material is SrₓBa₁₋ₓTiO₃, where x ranges from 0 to 1, having a thickness of about 2-100 nm and preferably a thickness of about 5-15 nm. Where the monocrystalline layer comprises a compound semiconductor material, the II-VI compound semiconductor material can be, for example, zinc selenide (ZnSe) or zinc sulfur selenide (ZnSSe). A suitable template for this material system includes 1-10 monolayers of zinc-oxygen (Zn—O) followed by 1-2 monolayers of an excess of zinc followed by the selenidation of zinc on the surface. Alternatively, a template can be, for example, 1-10 monolayers of strontium-sulfur (Sr—S) followed by the ZnSeS.

### EXAMPLE 4

This embodiment of the invention is an example of structure 40 illustrated in FIG. 2. Substrate 22, accommodating buffer layer 24, and monocrystalline material layer 26 can be similar to those described in example 1. In addition, an additional buffer layer 32 serves to alleviate any strains that might result from a mismatch of the crystal lattice of the accommodating buffer layer and the lattice of the monocrystalline material. Buffer layer 32 can be a layer of germanium or a GaAs, an aluminum gallium arsenide (AlGaAs), an indium gallium phosphide (InGaP), an aluminum gallium phosphide (AlGaP), an indium gallium arsenide (InGaAs), an aluminum indium phosphide (AlInP), a gallium arsenide phosphide (GaAsP), or an indium gallium phosphide (InGaP) strain compensated superlattice. In accordance with one aspect of this embodiment, buffer layer 32 includes a GaAsₓP₁₋ₓ superlattice, wherein the value of x ranges from 0 to 1. In accordance with another aspect, buffer layer 32 includes an In_{y}Ga_{1-y}P superlattice, wherein the value of y ranges from 0 to 1. By varying the value of x or y, as the case may be, the lattice constant is varied from bottom to top across the superlattice to create a match between lattice constants of the underlying oxide and the overlying monocrystalline material which in this example is a compound semiconductor material. The compositions of other compound semiconductor materials, such as those listed above, may also be similarly varied to manipulate the lattice constant of layer 32 in a like manner. The superlattice can have a thickness of about 50-500 nm and preferably has a thickness of about 100-200 nm. The template for this structure can be the same of that described in example 1. Alternatively, buffer layer 32 can be a layer of monocrystalline germanium having a thickness of 1-50 nm and preferably having a thickness of about 2-20 nm. In using a germanium buffer layer, a template layer of either germanium-strontium (Ge—Sr) or germanium-titanium (Ge—Ti) having a thickness of about one monolayer can be used as a nucleating site for the subsequent growth of the monocrystalline material layer which in this example is a compound semiconductor material. The formation of the oxide layer is capped with either a monolayer of strontium or a monolayer of titanium to act as a nucleating site for the subsequent deposition of the monocrystalline germanium. The monolayer of strontium or titanium provides a nucleating site to which the first monolayer of germanium can bond.

### EXAMPLE 5

This example also illustrates materials useful in a structure 40 as illustrated in FIG. 2. Substrate material 22, accommodating buffer layer 24, monocrystalline material layer 26 and template layer 30 can be the same as those described above in example 2. In addition, additional buffer layer 32 is inserted between the accommodating buffer layer and the overlying monocrystalline material layer. The buffer layer, a further monocrystalline material which in this instance comprises a semiconductor material, can be, for example, a graded layer of indium gallium arsenide (InGaAs) or indium aluminum arsenide (InAlAs). In accordance with one aspect of this embodiment, additional buffer layer 32 includes InGaAs, in which the indium composition varies from 0 to about 50%. The additional buffer layer 32 preferably has a thickness of about 10-30 nm. Varying the composition of the buffer layer from GaAs to InGaAs serves to provide a lattice match between the underlying monocrystalline oxide material and the overlying layer of monocrystalline material which in this example is a compound semiconductor material. Such a buffer layer is especially advantageous if there is a lattice mismatch between accommodating buffer layer 24 and monocrystalline material layer 26.

### EXAMPLE 6

This example provides exemplary materials useful in structure 34, as illustrated in FIG. 3. Substrate material 22, template layer 30, and monocrystalline material layer 26 may be the same as those described above in connection with example 1.

Amorphous layer 36 is an amorphous oxide layer which is suitably formed of a combination of amorphous intermediate layer materials (e.g., layer 28 materials as described above) and accommodating buffer layer materials (e.g., layer 24 materials as described above). For example, amorphous layer 36 may include a combination of SiOₓ and Sr_{z}Ba_{1-z}TiO₃ (where z ranges from 0 to 1),which combine or mix, at least partially, during an anneal process to form amorphous oxide layer 36.

The thickness of amorphous layer 36 may vary from application to application and may depend on such factors as desired insulating properties of layer 36, type of monocrystalline material comprising layer 26, and the like. In accordance with one exemplary aspect of the present embodiment, layer 36 thickness is about 2 nm to about 100 nm, preferably about 2-10 nm, and more preferably about 5-6 nm.

Layer 38 comprises a monocrystalline material that can be grown epitaxially over a monocrystalline oxide material such as material used to form accommodating buffer layer 24. In accordance with one embodiment of the invention, layer 38 includes the same materials as those comprising layer 26. For example, if layer 26 includes GaAs, layer 38 also includes GaAs. However, in accordance with other embodiments of the present invention, layer 38 may include materials different from those used to form layer 26. In accordance with one exemplary embodiment of the invention, layer 38 is about 1 monolayer to about 100 nm thick.

Referring again to FIGS. 1-3, substrate 22 is a monocrystalline substrate such as a monocrystalline silicon or gallium arsenide substrate. The crystalline structure of the monocrystalline substrate is characterized by a lattice constant and by a lattice orientation. In similar manner, accommodating buffer layer 24 is also a monocrystalline material and the lattice of that monocrystalline material is characterized by a lattice constant and a crystal orientation. The lattice constants of the accommodating buffer layer and the monocrystalline substrate must be closely matched or, alternatively, must be such that upon rotation of one crystal orientation with respect to the other crystal orientation, a substantial match in lattice constants is achieved. In this context the terms “substantially equal” and “substantially matched” mean that there is sufficient similarity between the lattice constants to permit the growth of a high quality crystalline layer on the underlying layer.

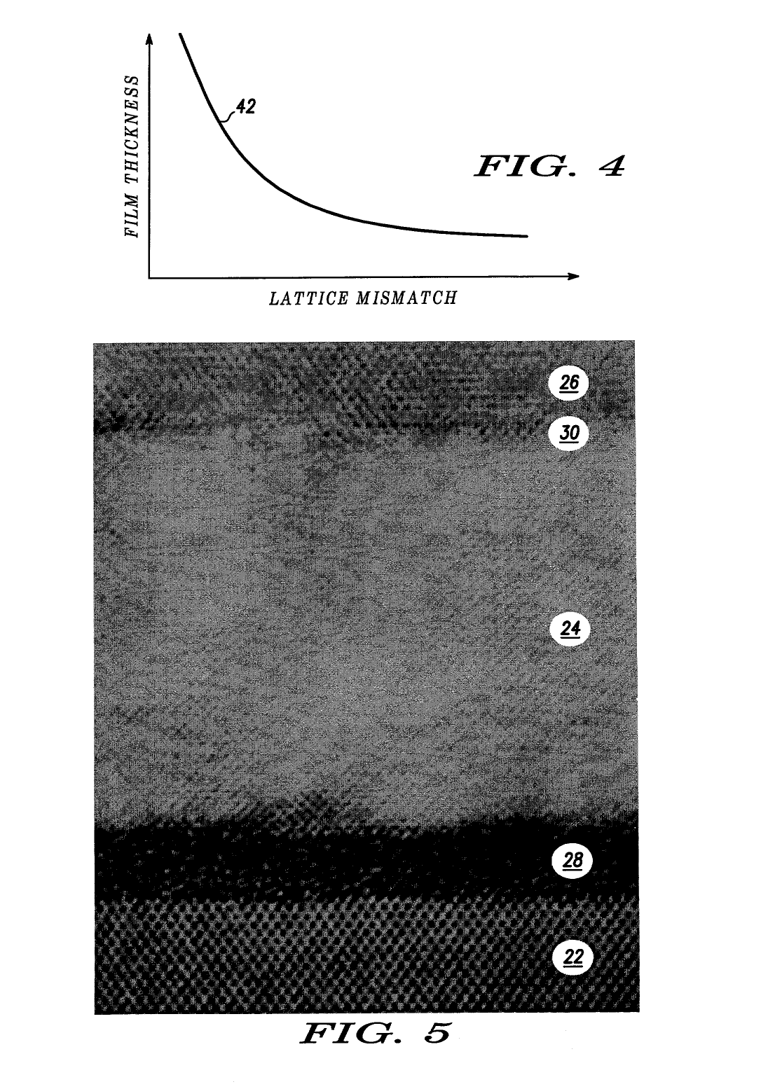

FIG. 4 illustrates graphically the relationship of the achievable thickness of a grown crystal layer of high crystalline quality as a function of the mismatch between the lattice constants of the host crystal and the grown crystal. Curve 42 illustrates the boundary of high crystalline quality material. The area to the right of curve 42 represents layers that have a large number of defects. With no lattice mismatch, it is theoretically possible to grow an infinitely thick, high quality epitaxial layer on the host crystal. As the mismatch in lattice constants increases, the thickness of achievable, high quality crystalline layer decreases rapidly. As a reference point, for example, if the lattice constants between the host crystal and the grown layer are mismatched by more than about 2%, monocrystalline epitaxial layers in excess of about 20 nm cannot be achieved.

In accordance with one embodiment of the invention, substrate 22 is a (100) or (111) oriented monocrystalline silicon wafer and accommodating buffer layer 24 is a layer of strontium barium titanate. Substantial matching of lattice constants between these two materials is achieved by rotating the crystal orientation of the titanate material by 45 degrees with respect to the crystal orientation of the silicon substrate wafer. The inclusion in the structure of amorphous interface layer 28, a silicon oxide layer in this example, if it is of sufficient thickness, serves to reduce strain in the titanate monocrystalline layer that might result from any mismatch in the lattice constants of the host silicon wafer and the grown titanate layer. As a result, in accordance with an embodiment of the invention, a high quality, thick, monocrystalline titanate layer is achievable.

Still referring to FIGS. 1-3, layer 26 is a layer of epitaxially grown monocrystalline material and that crystalline material is also characterized by a crystal lattice constant and a crystal orientation. In accordance with one embodiment of the invention, the lattice constant of layer 26 differs from the lattice constant of substrate 22. To achieve high crystalline quality in this epitaxially grown monocrystalline layer, the accommodating buffer layer must be of high crystalline quality. In addition, in order to achieve high crystalline quality in layer 26, substantial matching between the crystal lattice constant of the host crystal, in this case, the monocrystalline accommodating buffer layer, and the grown crystal is desired. With properly selected materials this substantial matching of lattice constants is achieved as a result of rotation of the crystal orientation of the grown crystal with respect to the orientation of the host crystal. For example, if the grown crystal is gallium arsenide, aluminum gallium arsenide, zinc selenide, or zinc sulfur selenide and the accommodating buffer layer is monocrystalline SrₓBa₁₋ₓTiO₃, substantial matching of crystal lattice constants of the two materials is achieved, wherein the crystal orientation of the grown layer is rotated by 45 degrees with respect to the orientation of the host monocrystalline oxide. Similarly, if the host material is a strontium or barium zirconate or a strontium or barium hafnate or barium tin oxide and the compound semiconductor layer is indium phosphide or gallium indium arsenide or aluminum indium arsenide, substantial matching of crystal lattice constants can be achieved by rotating the orientation of the grown crystal layer by 44 degrees with respect to the host oxide crystal. In some instances, a crystalline semiconductor buffer layer between the host oxide and the grown monocrystalline material layer can be used to reduce strain in the grown monocrystalline material layer that might result from small differences in lattice constants. Better crystalline quality in the grown monocrystalline material layer can thereby be achieved.

The following example illustrates a process, in accordance with one embodiment of the invention, for fabricating a semiconductor structure such as the structures depicted in FIGS. 1-3. The process starts by providing a monocrystalline semiconductor substrate comprising silicon or germanium. In accordance with a preferred embodiment of the invention, the semiconductor substrate is a silicon wafer having a (100) orientation. The substrate is preferably oriented on axis or, at most, about 4° off axis. At least a portion of the semiconductor substrate has a bare surface, although other portions of the substrate, as described below, may encompass other structures. The term “bare” in this context means that the surface in the portion of the substrate has been cleaned to remove any oxides, contaminants, or other foreign material. As is well known, bare silicon is highly reactive and readily forms a native oxide. The term “bare” is intended to encompass such a native oxide. A thin silicon oxide may also be intentionally grown on the semiconductor substrate, although such a grown oxide is not essential to the process in accordance with the invention. In order to epitaxially grow a monocrystalline oxide layer overlying the monocrystalline substrate, the native oxide layer must first be removed to expose the crystalline structure of the underlying substrate. The following process is preferably carried out by molecular beam epitaxy (MBE), although other epitaxial processes may also be used in accordance with the present invention. The native oxide can be removed by first thermally depositing a thin layer of strontium, barium, a combination of strontium and barium, or other alkaline earth metals or combinations of alkaline earth metals in an MBE apparatus. In the case where strontium is used, the substrate is then heated to a temperature of about 750° C. to cause the strontium to react with the native silicon oxide layer. The strontium serves to reduce the silicon oxide to leave a silicon oxide-free surface. The resultant surface, which exhibits an ordered 2×1 structure, includes strontium, oxygen, and silicon. The ordered 2×1 structure forms a template for the ordered growth of an overlying layer of a monocrystalline oxide. The template provides the necessary chemical and physical properties to nucleate the crystalline growth of an overlying layer.

In accordance with an alternate embodiment of the invention, the native silicon oxide can be converted and the substrate surface can be prepared for the growth of a monocrystalline oxide layer by depositing an alkaline earth metal oxide, such as strontium oxide, strontium barium oxide, or barium oxide, onto the substrate surface by MBE at a low temperature and by subsequently heating the structure to a temperature of about 750° C. At this temperature a solid state reaction takes place between the strontium oxide and the native silicon oxide causing the reduction of the native silicon oxide and leaving an ordered 2×1 structure with strontium, oxygen, and silicon remaining on the substrate surface. Again, this forms a template for the subsequent growth of an ordered monocrystalline oxide layer.

Following the removal of the silicon oxide from the surface of the substrate, in accordance with one embodiment of the invention, the substrate is cooled to a temperature in the range of about 200-800° C. and a layer of strontium titanate is grown on the template layer by molecular beam epitaxy. The MBE process is initiated by opening shutters in the MBE apparatus to expose strontium, titanium and oxygen sources. The ratio of strontium and titanium is approximately 1:1. The partial pressure of oxygen is initially set at a minimum value to grow stoichiometric strontium titanate at a growth rate of about 0.3-0.5 nm per minute. After initiating growth of the strontium titanate, the partial pressure of oxygen is increased above the initial minimum value. The overpressure of oxygen causes the growth of an amorphous silicon oxide layer at the interface between the underlying substrate and the growing strontium titanate layer. The growth of the silicon oxide layer results from the diffusion of oxygen through the growing strontium titanate layer to the interface where the oxygen reacts with silicon at the surface of the underlying substrate. The strontium titanate grows as an ordered (100) monocrystal with the (100) crystalline orientation rotated by 45° with respect to the underlying substrate. Strain that otherwise might exist in the strontium titanate layer because of the small mismatch in lattice constant between the silicon substrate and the growing crystal is relieved in the amorphous silicon oxide intermediate layer.

After the strontium titanate layer has been grown to the desired thickness, the monocrystalline strontium titanate is capped by a template layer that is conducive to the subsequent growth of an epitaxial layer of a desired monocrystalline material. For example, for the subsequent growth of a monocrystalline compound semiconductor material layer of gallium arsenide, the MBE growth of the strontium titanate monocrystalline layer can be capped by terminating the growth with 1-2 monolayers of titanium, 1-2 monolayers of titanium-oxygen or with 1-2 monolayers of strontium-oxygen. Following the formation of this capping layer, arsenic is deposited to form a Ti—As bond, a Ti—O—As bond or a Sr—O—As. Any of these form an appropriate template for deposition and formation of a gallium arsenide monocrystalline layer. Following the formation of the template, gallium is subsequently introduced to the reaction with the arsenic and gallium arsenide forms. Alternatively, gallium can be deposited on the capping layer to form a Sr—O—Ga bond, and arsenic is subsequently introduced with the gallium to form the GaAs.

FIG. 5 is a high resolution Transmission Electron Micrograph (TEM) of semiconductor material manufactured in accordance with one embodiment of the present invention. Single crystal SrTiO₃ accommodating buffer layer 24 was grown epitaxially on silicon substrate 22. During this growth process, amorphous interfacial layer 28 is formed which relieves strain due to lattice mismatch. GaAs compound semiconductor layer 26 was then grown epitaxially using template layer 30.

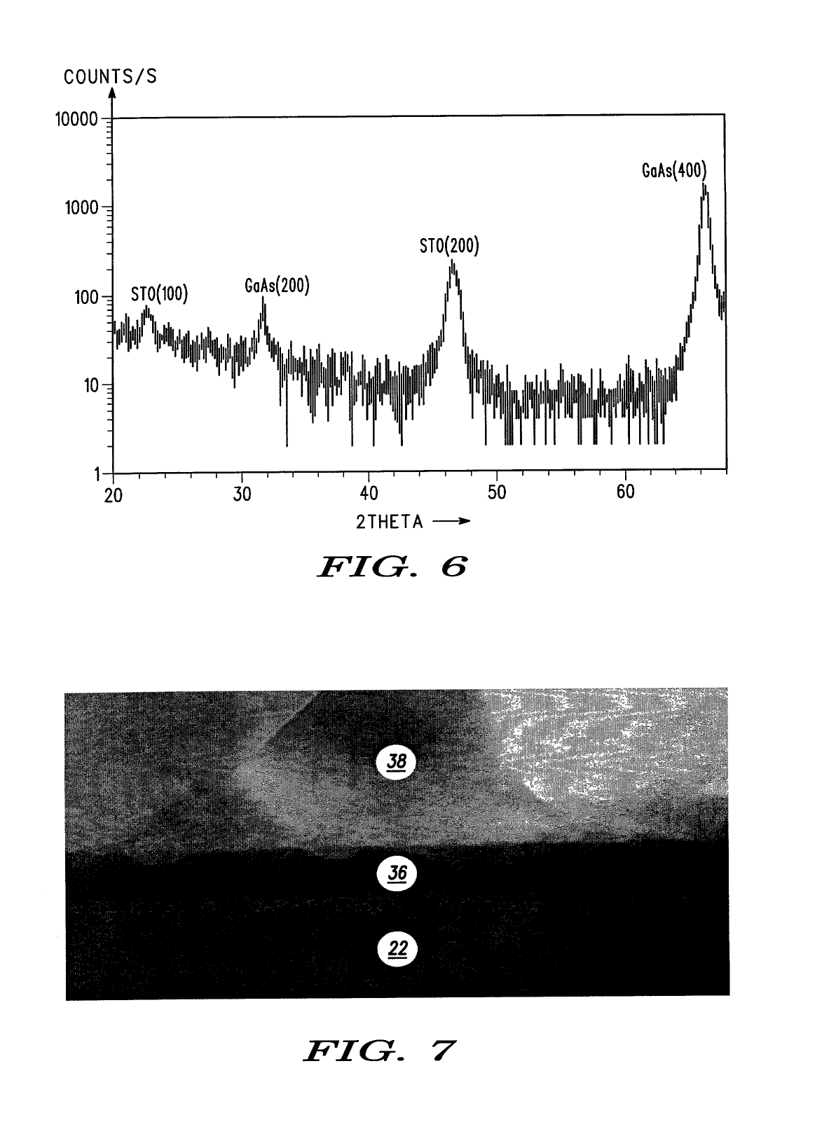

FIG. 6 illustrates an x-ray diffraction spectrum taken on a structure including GaAs monocrystalline layer 26 comprising GaAs grown on silicon substrate 22 using accommodating buffer layer 24. The peaks in the spectrum indicate that both the accommodating buffer layer 24 and GaAs compound semiconductor layer 26 are single crystal and (100) orientated.

The structure illustrated in FIG. 2 can be formed by the process discussed above with the addition of an additional buffer layer deposition step. The additional buffer layer 32 is formed overlying the template layer before the deposition of the monocrystalline material layer. If the buffer layer is a monocrystalline material comprising a compound semiconductor superlattice, such a superlattice can be deposited, by MBE for example, on the template described above. If instead the buffer layer is a monocrystalline material layer comprising a layer of germanium, the process above is modified to cap the strontium titanate monocrystalline layer with a final layer of either strontium or titanium and then by depositing germanium to react with the strontium or titanium. The germanium buffer layer can then be deposited directly on this template.

Structure 34, illustrated in FIG. 3, may be formed by growing an accommodating buffer layer, forming an amorphous oxide layer over substrate 22, and growing semiconductor layer 38 over the accommodating buffer layer, as described above. The accommodating buffer layer and the amorphous oxide layer are then exposed to an anneal process sufficient to change the crystalline structure of the accommodating buffer layer from monocrystalline to amorphous, thereby forming an amorphous layer such that the combination of the amorphous oxide layer and the now amorphous accommodating buffer layer form a single amorphous oxide layer 36. Layer 26 is then subsequently grown over layer 38. Alternatively, the anneal process may be carried out subsequent to growth of layer 26.

In accordance with one aspect of this embodiment, layer 36 is formed by exposing substrate 22, the accommodating buffer layer, the amorphous oxide layer, and monocrystalline layer 38 to a rapid thermal anneal process with a peak temperature of about 700° C. to about 1000° C. and a process time of about 5 seconds to about 10 minutes. However, other suitable anneal processes may be employed to convert the accommodating buffer layer to an amorphous layer in accordance with the present invention. For example, laser annealing, electron beam annealing, or “conventional” thermal annealing processes (in the proper environment) may be used to form layer 36. When conventional thermal annealing is employed to form layer 36, an overpressure of one or more constituents of layer 30 may be required to prevent degradation of layer 38 during the anneal process. For example, when layer 38 includes GaAs, the anneal environment preferably includes an overpressure of arsenic to mitigate degradation of layer 38.

As noted above, layer 38 of structure 34 may include any materials suitable for either of layers 32 or 26. Accordingly, any deposition or growth methods described in connection with either layer 32 or 26, may be employed to deposit layer 38.

FIG. 7 is a high resolution TEM of semiconductor material manufactured in accordance with the embodiment of the invention illustrated in FIG. 3. In accordance with this embodiment, a single crystal SrTiO₃ accommodating buffer layer was grown epitaxially on silicon substrate 22. During this growth process, an amorphous interfacial layer forms as described above. Next, additional monocrystalline layer 38 comprising a compound semiconductor layer of GaAs is formed above the accommodating buffer layer and the accommodating buffer layer is exposed to an anneal process to form amorphous oxide layer 36.

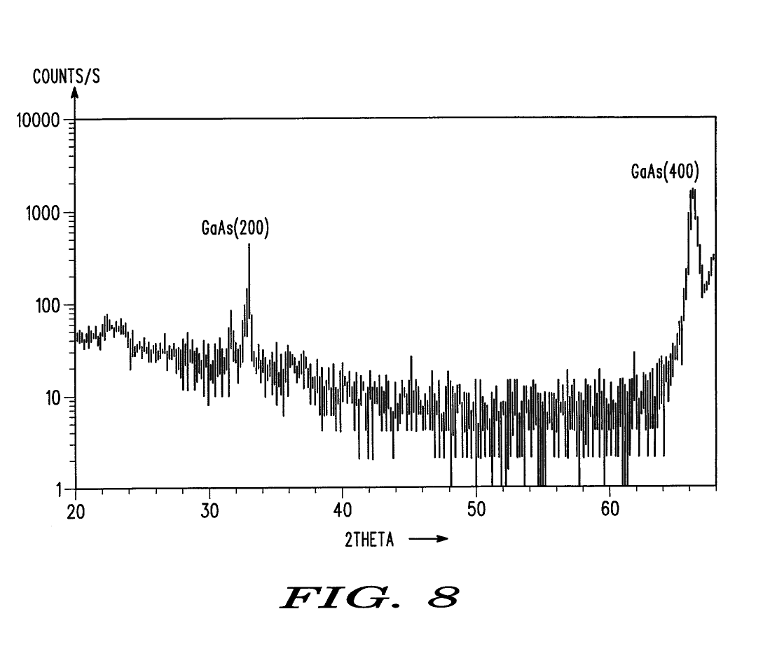

FIG. 8 illustrates an x-ray diffraction spectrum taken on a structure including additional monocrystalline layer 38 comprising a GaAs compound semiconductor layer and amorphous oxide layer 36 formed on silicon substrate 22. The peaks in the spectrum indicate that GaAs compound semiconductor layer 38 is single crystal and (100) orientated and the lack of peaks around 40 to 50 degrees indicates that layer 36 is amorphous.

The process described above illustrates a process for forming a semiconductor structure including a silicon substrate, an overlying oxide layer, and a monocrystalline material layer comprising a gallium arsenide compound semiconductor layer by the process of molecular beam epitaxy. The process can also be carried out by the process of chemical vapor deposition (CVD), metal organic chemical vapor deposition (MOCVD), migration enhanced epitaxy (MEE), atomic layer epitaxy (ALE), physical vapor deposition (PVD), chemical solution deposition (CSD), pulsed laser deposition (PLD), or the like. Further, by a similar process, other monocrystalline accommodating buffer layers such as alkaline earth metal titanates, zirconates, hafnates, tantalates, vanadates, ruthenates, and niobates alkaline earth metal tin-based perovskites, lanthanum aluminate, lanthanum scandium oxide, and gadolinium oxide can also be grown. Further, by a similar process such as MBE, other monocrystalline material layers comprising other III-V and II-VI monocrystalline compound semiconductors, semiconductors, metals and non-metals can be deposited overlying the monocrystalline oxide accommodating buffer layer.

Each of the variations of monocrystalline material layer and monocrystalline oxide accommodating buffer layer uses an appropriate template for initiating the growth of the monocrystalline material layer. For example, if the accommodating buffer layer is an alkaline earth metal zirconate, the oxide can be capped by a thin layer of zirconium. The deposition of zirconium can be followed by the deposition of arsenic or phosphorus to react with the zirconium as a precursor to depositing indium gallium arsenide, indium aluminum arsenide, or indium phosphide respectively. Similarly, if the monocrystalline oxide accommodating buffer layer is an alkaline earth metal hafnate, the oxide layer can be capped by a thin layer of hafnium. The deposition of hafnium is followed by the deposition of arsenic or phosphorous to react with the hafnium as a precursor to the growth of an indium gallium arsenide, indium aluminum arsenide, or indium phosphide layer, respectively. In a similar manner, strontium titanate can be capped with a layer of strontium or strontium and oxygen and barium titanate can be capped with a layer of barium or barium and oxygen. Each of these depositions can be followed by the deposition of arsenic or phosphorus to react with the capping material to form a template for the deposition of a monocrystalline material layer comprising compound semiconductors such as indium gallium arsenide, indium aluminum arsenide, or indium phosphide.

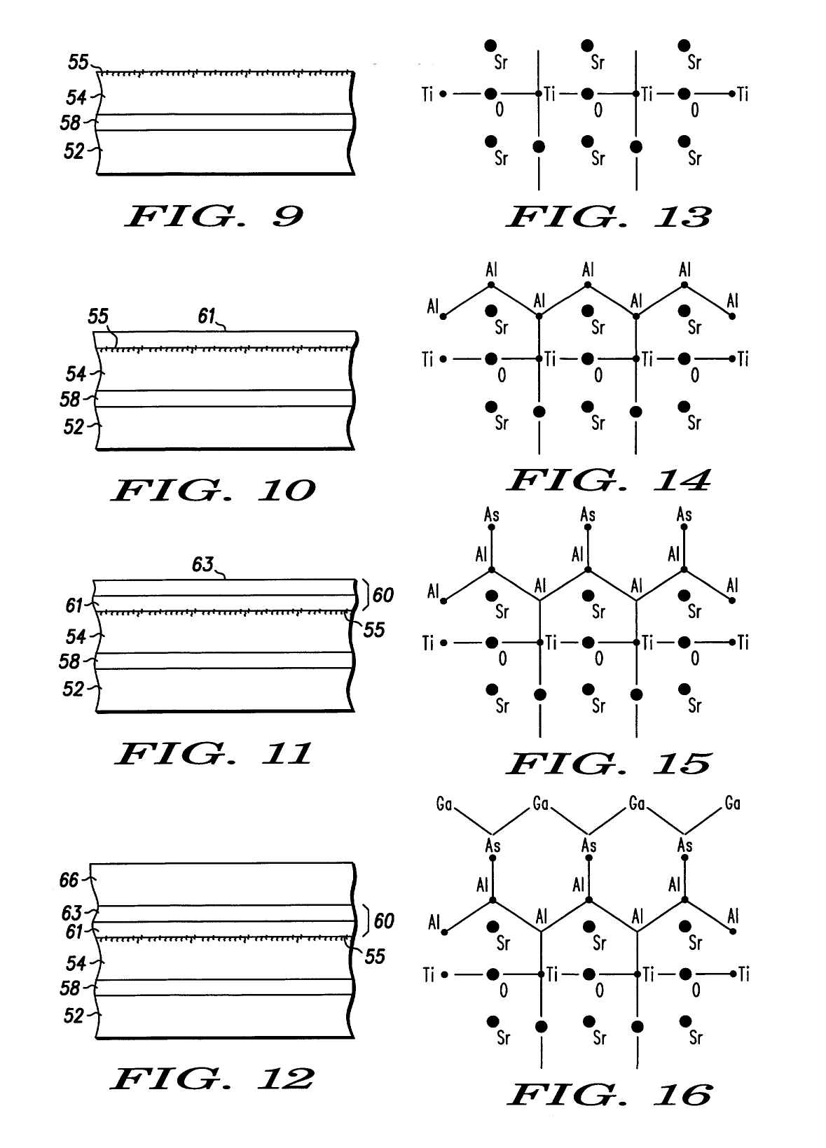

The formation of a device structure in accordance with another embodiment of the invention is illustrated schematically in cross-section in FIGS. 9-12. Like the previously described embodiments referred to in FIGS. 1-3, this embodiment of the invention involves the process of forming a compliant substrate utilizing the epitaxial growth of single crystal oxides, such as the formation of accommodating buffer layer 24 previously described with reference to FIGS. 1 and 2 and amorphous layer 36 previously described with reference to FIG. 3, and the formation of a template layer 30. However, the embodiment illustrated in FIGS. 9-12 utilizes a template that includes a surfactant to facilitate layer-by-layer monocrystalline material growth.

Turning now to FIG. 9, an amorphous intermediate layer 58 is grown on substrate 52 at the interface between substrate 52 and a growing accommodating buffer layer 54, which is preferably a monocrystalline crystal oxide layer, by the oxidation of substrate 52 during the growth of layer 54. Layer 54 is preferably a monocrystalline oxide material such as a monocrystalline layer of Sr_{z}Ba_{1-z}TiO₃ where z ranges from 0 to 1. However, layer 54 may also comprise any of those compounds previously described with reference layer 24 in FIGS. 1-2 and any of those compounds previously described with reference to layer 36 in FIG. 3 which is formed from layers 24 and 28 referenced in FIGS. 1 and 2.

Layer 54 is grown with a strontium (Sr) terminated surface represented in FIG. 9 by hatched line 55 which is followed by the addition of a template layer 60 which includes a surfactant layer 61 and capping layer 63 as illustrated in FIGS. 10 and 11. Surfactant layer 61 may comprise, but is not limited to, elements such as Al, In and Ga, but will be dependent upon the composition of layer 54 and the overlying layer of monocrystalline material for optimal results. In one exemplary embodiment, aluminum (Al) is used for surfactant layer 61 and functions to modify the surface and surface energy of layer 54. Preferably, surfactant layer 61 is epitaxially grown, to a thickness of one to two monolayers, over layer 54 as illustrated in FIG. 10 by way of molecular beam epitaxy (MBE), although other epitaxial processes may also be performed including chemical vapor deposition (CVD), metal organic chemical vapor deposition (MOCVD), migration enhanced epitaxy (MEE), atomic layer epitaxy (ALE), physical vapor deposition (PVD), chemical solution deposition (CSD), pulsed laser deposition (PLD), or the like.

Surfactant layer 61 is then exposed to a Group V element such as arsenic, for example, to form capping layer 63 as illustrated in FIG. 11. Surfactant layer 61 may be exposed to a number of materials to create capping layer 63 such as elements which include, but are not limited to, As, P, Sb and N. Surfactant layer 61 and capping layer 63 combine to form template layer 60.

Monocrystalline material layer 66, which in this example is a compound semiconductor such as GaAs, is then deposited via MBE, CVD, MOCVD, MEE, ALE, PVD, CSD, PLD, and the like to form the final structure illustrated in FIG. 12.

FIGS. 13-16 illustrate possible molecular bond structures for a specific example of a compound semiconductor structure formed in accordance with the embodiment of the invention illustrated in FIGS. 9-12. More specifically, FIGS. 13-16 illustrate the growth of GaAs (layer 66) on the strontium terminated surface of a strontium titanate monocrystalline oxide (layer 54) using a surfactant containing template (layer 60).

The growth of a monocrystalline material layer 66 such as GaAs on an accommodating buffer layer 54 such as a strontium titanium oxide over amorphous interface layer 58 and substrate layer 52, both of which may comprise materials previously described with reference to layers 28 and 22, respectively in FIGS. 1 and 2, illustrates a critical thickness of about 1000 Angstroms where the two-dimensional (2D) and three-dimensional (3D) growth shifts because of the surface energies involved. In order to maintain a true layer by layer growth (Frank Van der Mere growth), the following relationship must be satisfied:

δ_{STO>(δ}_{INT}+δ_{GaAs})

where the surface energy of the monocrystalline oxide layer 54 must be greater than the surface energy of the amorphous interface layer 58 added to the surface energy of the GaAs layer 66. Since it is impracticable to satisfy this equation, a surfactant containing template was used, as described above with reference to FIGS. 10-12, to increase the surface energy of the monocrystalline oxide layer 54 and also to shift the crystalline structure of the template to a diamond-like structure that is in compliance with the original GaAs layer.

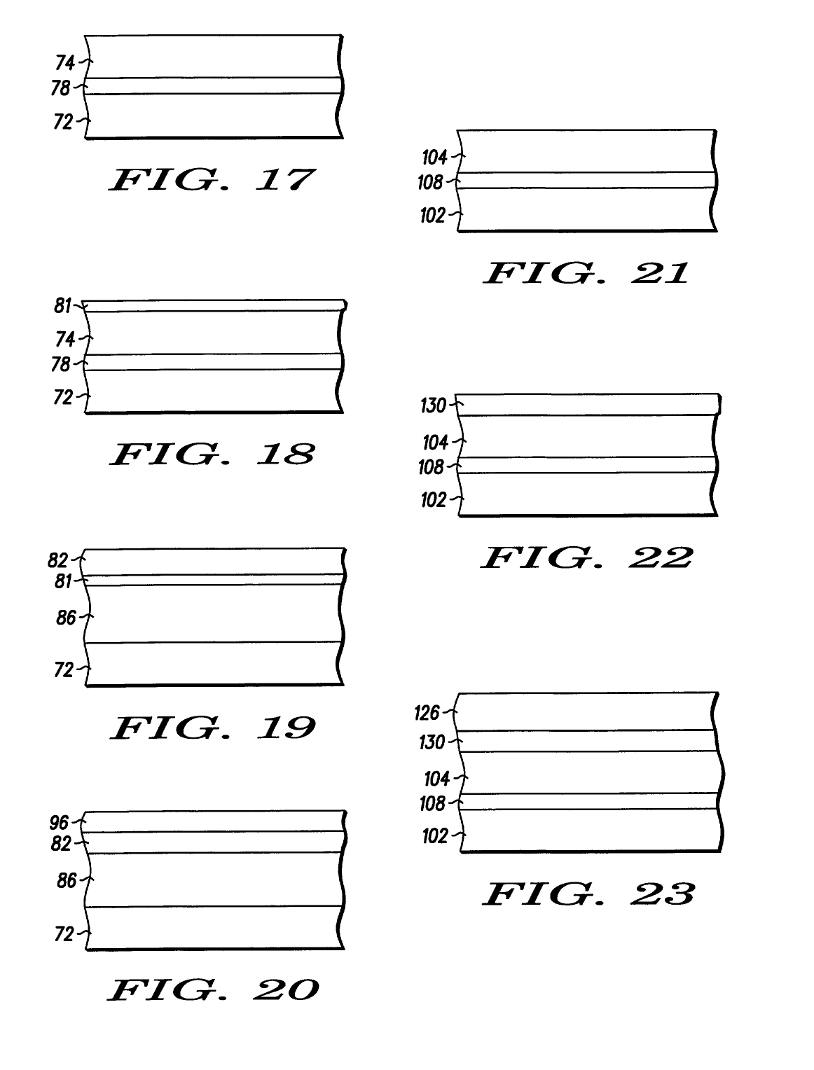

FIG. 13 illustrates the molecular bond structure of a strontium terminated surface of a strontium titanate monocrystalline oxide layer. An aluminum surfactant layer is deposited on top of the strontium terminated surface and bonds with that surface as illustrated in FIG. 14, which reacts to form a capping layer comprising a monolayer of Al₂Sr having the molecular bond structure illustrated in FIG. 14 which forms a diamond-like structure with an sp³ hybrid terminated surface that is compliant with compound semiconductors such as GaAs. The structure is then exposed to As to form a layer of AlAs as shown in FIG. 15. GaAs is then deposited to complete the molecular bond structure illustrated in FIG. 16 which has been obtained by 2D growth. The GaAs can be grown to any thickness for forming other semiconductor structures, devices, or integrated circuits. Alkaline earth metals such as those in Group IIA are those elements preferably used to form the capping surface of the monocrystalline oxide layer 54 because they are capable of forming a desired molecular structure with aluminum.

In this embodiment, a surfactant containing template layer aids in the formation of a compliant substrate for the monolithic integration of various material layers including those comprised of Group III-V compounds to form high quality semiconductor structures, devices and integrated circuits. For example, a surfactant containing template may be used for the monolithic integration of a monocrystalline material layer such as a layer comprising Germanium (Ge), for example, to form high efficiency photocells. Turning now to FIGS. 17-20, the formation of a device structure in accordance with still another embodiment of the invention is illustrated in cross-section. This embodiment utilizes the formation of a compliant substrate which relies on the epitaxial growth of single crystal oxides on silicon followed by the epitaxial growth of single crystal silicon onto the oxide.

An accommodating buffer layer 74 such as a monocrystalline oxide layer is first grown on a substrate layer 72, such as silicon, with an amorphous interface layer 78 as illustrated in FIG. 17. Monocrystalline oxide layer 74 may be comprised of any of those materials previously discussed with reference to layer 24 in FIGS. 1 and 2, while amorphous interface layer 78 is preferably comprised of any of those materials previously described with reference to the layer 28 illustrated in FIGS. 1 and 2. Substrate 72, although preferably silicon, may also comprise any of those materials previously described with reference to substrate 22 in FIGS. 1-3.

Next, a silicon layer 81 is deposited over monocrystalline oxide layer 74 via MBE, CVD, MOCVD, MEE, ALE, PVD, CSD, PLD, and the like as illustrated in FIG. 18 with a thickness of a few hundred Angstroms but preferably with a thickness of about 50 Angstroms. Monocrystalline oxide layer 74 preferably has a thickness of about 20 to 100 Angstroms.

Rapid thermal annealing is then conducted in the presence of a carbon source such as acetylene or methane, for example at a temperature within a range of about 800° C. to 1000° C. to form capping layer 82 and silicate amorphous layer 86. However, other suitable carbon sources may be used as long as the rapid thermal annealing step functions to amorphize the monocrystalline oxide layer 74 into a silicate amorphous layer 86 and carbonize the top silicon layer 81 to form capping layer 82 which in this example would be a silicon carbide (SiC) layer as illustrated in FIG. 19. The formation of amorphous layer 86 is similar to the formation of layer 36 illustrated in FIG. 3 and may comprise any of those materials described with reference to layer 36 in FIG. 3 but the preferable material will be dependent upon the capping layer 82 used for silicon layer 81.

Finally, a compound semiconductor layer 96, such as gallium nitride (GaN) is grown over the SiC surface by way of MBE, CVD, MOCVD, MEE, ALE, PVD, CSD, PLD, or the like to form a high quality compound semiconductor material for device formation. More specifically, the deposition of GaN and GaN based systems such as GaInN and AlGaN will result in the formation of dislocation nets confined at the silicon/amorphous region. The resulting nitride containing compound semiconductor material may comprise elements from groups III, IV and V of the periodic table and is defect free.

Although GaN has been grown on SiC substrate in the past, this embodiment of the invention possesses a one step formation of the compliant substrate containing a SiC top surface and an amorphous layer on a Si surface. More specifically, this embodiment of the invention uses an intermediate single crystal oxide layer that is amorphosized to form a silicate layer which adsorbs the strain between the layers. Moreover, unlike past use of a SiC substrate, this embodiment of the invention is not limited by wafer size which is usually less than 50 mm in diameter for prior art SiC substrates.

The monolithic integration of nitride containing semiconductor compounds containing group III-V nitrides and silicon devices can be used for high temperature RF applications and optoelectronics. GaN systems have particular use in the photonic industry for the blue/green and UV light sources and detection. High brightness light emitting diodes (LEDs) and lasers may also be formed within the GaN system.

FIGS. 21-23 schematically illustrate, in cross-section, the formation of another embodiment of a device structure in accordance with the invention. This embodiment includes a compliant layer that functions as a transition layer that uses clathrate or Zint1 type bonding. More specifically, this embodiment utilizes an intermetallic template layer to reduce the surface energy of the interface between material layers thereby allowing for two dimensional layer by layer growth.

The structure illustrated in FIG. 21 includes a monocrystalline substrate 102, an amorphous interface layer 108 and an accommodating buffer layer 104. Amorphous interface layer 108 is formed on substrate 102 at the interface between substrate 102 and accommodating buffer layer 104 as previously described with reference to FIGS. 1 and 2. Amorphous interface layer 108 may comprise any of those materials previously described with reference to amorphous interface layer 28 in FIGS. 1 and 2. Substrate 102 is preferably silicon but may also comprise any of those materials previously described with reference to substrate 22 in FIGS. 1-3.

A template layer 130 is deposited over accommodating buffer layer 104 as illustrated in FIG. 22 and preferably comprises a thin layer of Zint1 type phase material composed of metals and metalloids having a great deal of ionic character. As in previously described embodiments, template layer 130 is deposited by way of MBE, CVD, MOCVD, MEE, ALE, PVD, CSD, PLD, or the like to achieve a thickness of one monolayer. Template layer 130 functions as a Asoft@layer with non-directional bonding but high crystallinity which absorbs stress build up between layers having lattice mismatch. Materials for template 130 may include, but are not limited to, materials containing Si, Ga, In, and Sb such as, for example, AlSr₂, (MgCaYb)Ga₂, (Ca,Sr,Eu, Yb)In₂, BaGe₂As, and SrSn₂As₂

A monocrystalline material layer 126 is epitaxially grown over template layer 130 to achieve the final structure illustrated in FIG. 23. As a specific example, an SrAl₂ layer may be used as template layer 130 and an appropriate monocrystalline material layer 126 such as a compound semiconductor material GaAs is grown over the SrAl₂. The Al—Ti (from the accommodating buffer layer of layer of Sr_{z}Ba_{1-z}TiO₃ where z ranges from 0 to 1) bond is mostly metallic while the Al—As (from the GaAs layer) bond is weakly covalent. The Sr participates in two distinct types of bonding with part of its electric charge going to the oxygen atoms in the lower accommodating buffer layer 104 comprising Sr_{z}Ba_{1-z}TiO₃ to participate in ionic bonding and the other part of its valence charge being donated to Al in a way that is typically carried out with Zint1 phase materials. The amount of the charge transfer depends on the relative electronegativity of elements comprising the template layer 130 as well as on the interatomic distance. In this example, Al assumes an sp³ hybridization and can readily form bonds with monocrystalline material layer 126, which in this example, comprises compound semiconductor material GaAs.

The compliant substrate produced by use of the Zint1 type template layer used in this embodiment can absorb a large strain without a significant energy cost. In the above example, the bond strength of the Al is adjusted by changing the volume of the SrAl₂ layer thereby making the device tunable for specific applications which include the monolithic integration of III-V and Si devices and the monolithic integration of high-k dielectric materials for CMOS technology.

Clearly, those embodiments specifically describing structures having compound semiconductor portions and Group IV semiconductor portions, are meant to illustrate embodiments of the present invention and not limit the present invention. There are a multiplicity of other combinations and other embodiments of the present invention. For example, the present invention includes structures and methods for fabricating material layers which form semiconductor structures, devices and integrated circuits including other layers such as metal and non-metal layers. More specifically, the invention includes structures and methods for forming a compliant substrate which is used in the fabrication of semiconductor structures, devices and integrated circuits and the material layers suitable for fabricating those structures, devices, and integrated circuits. By using embodiments of the present invention, it is now simpler to integrate devices that include monocrystalline layers comprising semiconductor and compound semiconductor materials as well as other material layers that are used to form those devices with other components that work better or are easily and/or inexpensively formed within semiconductor or compound semiconductor materials. This allows a device to be shrunk, the manufacturing costs to decrease, and yield and reliability to increase.

In accordance with one embodiment of this invention, a monocrystalline semiconductor or compound semiconductor wafer can be used in forming monocrystalline material layers over the wafer. In this manner, the wafer is essentially a “handle” wafer used during the fabrication of semiconductor electrical components within a monocrystalline layer overlying the wafer. Therefore, electrical components can be formed within semiconductor materials over a wafer of at least approximately 200 millimeters in diameter and possibly at least approximately 300 millimeters.

By the use of this type of substrate, a relatively inexpensive “handle” wafer overcomes the fragile nature of compound semiconductor or other monocrystalline material wafers by placing them over a relatively more durable and easy to fabricate base material. Therefore, an integrated circuit can be formed such that all electrical components, and particularly all active electronic devices, can be formed within or using the monocrystalline material layer even though the substrate itself may include a monocrystalline semiconductor material. Fabrication costs for compound semiconductor devices and other devices employing non-silicon monocrystalline materials should decrease because larger substrates can be processed more economically and more readily compared to the relatively smaller and more fragile substrates (e.g. conventional compound semiconductor wafers).

### EXAMPLE 7

Referring to FIGS. 24-27, semiconductor structure 267 is formed in accordance with another embodiment of the invention. Similar, at least initially, to that described for FIG. 3, the process in FIG. 24 begins by growing the accommodating buffer layer 24, comprised at least initially of monocrystalline perovskite oxide, on a monocrystalline silicon substrate 22, and then forming an interfacial oxide layer 28 between the buffer layer 24 and the silicon substrate 22. Then, template 30 can be formed upon the buffer layer 24. Suitable techniques and considerations for forming buffer layer 24, interfacial amorphous oxide layer 28, and the template 30 for this embodiment are also described above in connection with FIGS. 1-3 and reference is made thereto. As described above, template layer 30 generally has a thickness ranging form about 1 to about 10 monolayers. Next, a monocrystalline compound semiconductor seed film 261 is epitaxially grown over the accommodating buffer layer 24 to provide the intermediate structure shown in FIG. 24. The compound semiconductor film 261 generally is grown to a positive thickness of about 10 Angstroms to about 2,500 Angstroms, and particularly between about 10 Angstroms to about 750 Angstroms, although its thickness is not necessarily limited thereto as long as it permits contamination removal and meets any other requirements related to it as described herein.

Referring to FIG. 25, the intermediate product illustrated in FIG. 24 is subjected to a surface oxidation treatment sufficient to substantially uniformly oxidize material present in the surface 262 of seed film 261 to form a oxidized surface region 263 on the remaining non-oxidized compound semiconductor seed film 264. Atomic metallic contaminants that have surface segregated from the perovskite oxide film 24 generally tend to be concentrated at the surface 262 of the seed film 261, although some contamination of the bulk of seed film 261 also tends to occur. This phenomenon has been confirmed by observations made by secondary ion mass spectroscopy (SIMS) which confirm the presence of atomic metal constituents of the types in perovskite oxide film 24 on the surface of the overlying compound semiconductor seed film 261 before it is surface treated according to this embodiment of the invention.

As mentioned above, a surface oxidation is performed sufficient to oxidize a relatively thin stratum 263 of the entire original thickness of the monocrystalline compound semiconductor seed film 261. Generally, this surface oxidation performed on monocrystalline compound semiconductor film 261 extends depthwise, i.e., in the direction inward from surface 262 towards the bulk of seed film 261, a positive value distance of about 25% or less, particularly about 10% or less, and more particularly about 5% or less, of the entire original thickness of monocrystalline compound semiconductor film 261. In any case, the depth of the surface oxidation 263 preferably will be deep enough to encompass a significant amount or even essentially all of the contaminant metal located at and near the surface region 262 of the monocrystalline compound semiconductor film 261.

The surface oxidation treatment can be implemented using any technique suitable for effecting controlled oxidation of the surface of the monocrystalline compound semiconductor region 261. An oxidizing atmosphere is generated in or conducted into the growth chamber where the workpiece is situated. For instance, the intermediate structure shown in FIG. 24 is placed in a growth chamber, which can be either the same chamber in which the perovskite oxide film 24 was grown or, alternatively, a different growth chamber in which the monocrystalline compound semiconductor layer 266 will be grown. These growth chambers, for example, can be UBE chambers. In order to oxidize surface material of the monocrystalline compound semiconductor film 261, oxygen gas can be fed into a tube or chamber in which a plasma is struck effective to generate oxygen radicals, and these oxygen radicals are then transported to the surface 262 of the intermediate structure located in a growth chamber where they interact with Group III-V compound semiconductor material in the seed film 261 to form an oxide film 263. This procedure can be conducted at ambient temperature. Vacuum conditions are provided in the growth chamber where the workpiece is located. If the seed film 261 is GaAs, a mixed oxide of gallium oxide (Ga₂O₃) and arsenic oxide (As₂O₃) is formed to constitute oxide film 263. The solid GaAs oxide is a mixed composition of Ga₂O₃ and As₂O₃. When they sublime they form Ga₂O+oxygen and many different arsenic oxide species, such as AsO, As₂O₃, As₃O₄, and As₄O₆.

Alternatively, ozone could be generated by exposing oxygen to ultraviolet light in an exposure tube or chamber, and the conducting the ozone to the workpiece in the growth chamber where it interacts with the surface material of the compound semiconductor film 261 to form oxide film 263.

In one aspect, the monocrystalline compound semiconductor film 261 and monocrystalline compound semiconductor layer 266 are formed of the same or essentially the same Group III-V compound semiconductor material. Suitable examples of the Group III-V compound semiconductor materials useful in this regard in forming monocrystalline compound semiconductor film 261 and monocrystalline compound semiconductor layer 266 include those described herein in connection with layer 26 illustrated in FIGS. 1-3, and reference is made thereto.

The conversion of the Group III-V compound semiconductor material in the seed film 261 to oxide film 263 effectively reduces the thickness of seed film 261 to leave a remaining seed film portion 264 with a reduced thickness. The rate of oxidation of the surface 262 of seed film 261 can be controlled by adjusting the oxygen feed rate, plasma conditions, and so forth. Once the desired thickness of oxide film 263 is achieved, the surface oxidation procedure is halted.

Referring now to FIG. 26, the oxidized film 263 is then removed from the surface 265 of the remaining, non-oxidized monocrystalline compound semiconductor film 264. This is done by desorbing the oxide film 263. Desorption is achieved by heating the oxide film 263 to a temperature and for a time effective to volatize and remove at least a significant amount, or even essentially all, of the material of the oxide film 263. Generally, removal of the material of the oxide film 263 is conducted sufficiently such that any remainder thereof does not significantly adversely effect subsequent crystal growth and/or device performance.

In accordance with one aspect of this embodiment, oxide film 263 is heated to a surface temperature sufficient to volatize the metal oxide constituents of the film. For Group III-V oxide materials, a surface temperature of at least about 600° C. generally will be needed to induce desorption of the oxide film 263 material. For instance, arsenic oxide can be volatized and removed when heated to about 600° C. to about 650° C., while gallium oxide can be volatized and removed when heated to about 680° C. or higher. Thus, for desorbing oxidized gallium arsenide, the oxidized film 263 can be heated to the range of about 650 to 700° C.

The desorption procedure can be performed in the same or a different process chamber as the chamber in which the oxide film 263 was formed. The desorption procedure is performed under high vacuum conditions, such as about 10⁻⁷ torr or even lower pressures. The peak surface temperature of oxide film 263 can be monitored and measured during the desorption procedure using, for example, an optical pyrometer. The process time depends on the type of heating used, the temperature, the pressure, and the thickness of the oxide film 263, and so forth, and generally will be from about 10 seconds to 10 minutes. The desorption procedure should be performed in a non-oxidizing environment. Suitable heating techniques for the desorption procedure include, for example, radiative heating from the back (i.e., the silicon side), laser annealing, electron beam annealing, or thermal furnace or tube processes.

For example, the outer exposed surface of the oxide film 263 can be irradiated with a laser effective to thermally excite the irradiated portions thereof sufficient to volatize the metal oxide(s). The laser source is not particularly limited as long as it can provide heat-generating radiation providing the functionality described herein, and the laser is not limited in the oscillation wavelength range. For instance, an excimer laser, a free electron laser, a solid laser, or a continuous wave laser may be used. Where an excimer laser is used, pulse irradiation optionally may be used. The laser set-up used can include arrangements generally known for use in laser-assisted MBE growth processing.

During the heating procedure used for desorbing the oxide film 263 in the instance of a seed film 264 containing arsenic, it can be helpful to direct a beam of atomic arsenic onto the oxide film 263 during the desorption process to reduce decomposition and degradation of the underlying seed film 264. Alternatively, during desorption of the oxide film 263, an overpressure of one or more constituents of capping/template layer 30 also can be used to help reduce degradation of seed film 264 during the desorption process. For example, when seed film 264 includes GaAs, the heated environment can include an overpressure of arsenic to mitigate degradation of seed film 264. For example, the overpressure may help to inhibit possible disassociation of arsenic from the gallium in the GaAs film. Such overpressure may also be applied during laser or e-beam heat treatments used for the desorption of the oxide film 263, in addition to or in lieu of the electron beam treatment described above for this general purpose.

At this juncture of the process scheme, a significant proportion or even substantially all of any perovskite oxide-origin metal contaminants previously located in the surface 262 of the workpiece have been effectively removed from the structure. A relatively cleaner and flat new surface 265 is provided on remaining compound semiconductor film 264 for conducting further processing and epitaxial regrowth thereon in particular.

Referring now to FIG. 27, a compound semiconductor layer 266 is subsequently grown on seed film 264 to yield composite semiconductor structure 267. To form layer 266, a thicker layer of the compound semiconductor material used in forming seed layer 261 is epitaxially grown thereon, after the surface oxidation and desorption procedure. Otherwise, layer 266 is formed in similar manners and is made of similar materials, e.g., group III-V compound semiconductors, as described herein for monocrystalline compound semiconductor layer 26.

Remaining monocrystalline compound semiconductor seed film 264 generally is left in a substantially uniform thickness of generally between about 10 Angstroms to about 2,250 Angstroms, particularly between about 10 Angstroms to about 1,000 Angstroms, and more particularly between about 50 to about 250 Angstroms. However, the thickness of seed film 264 is not necessarily limited thereto as long as its other requirements related to it, such as providing an adequate growth site for forming monocrystalline compound semiconductor layer 266 thereon. The monocrystalline compound semiconductor layer 266 generally has a thickness of about 1 nm to about 100 micrometers (μm) and preferably a thickness of about 0.5 μm to 10 μm.

As noted above, seed film 264 of structure 267 is comprised of the same or essentially the same compound semiconductor material used in layer 266. Accordingly, any deposition or growth methods described herein in connection with layer 266, may be employed to deposit film 261, albeit at a smaller thickness in comparison thereto.

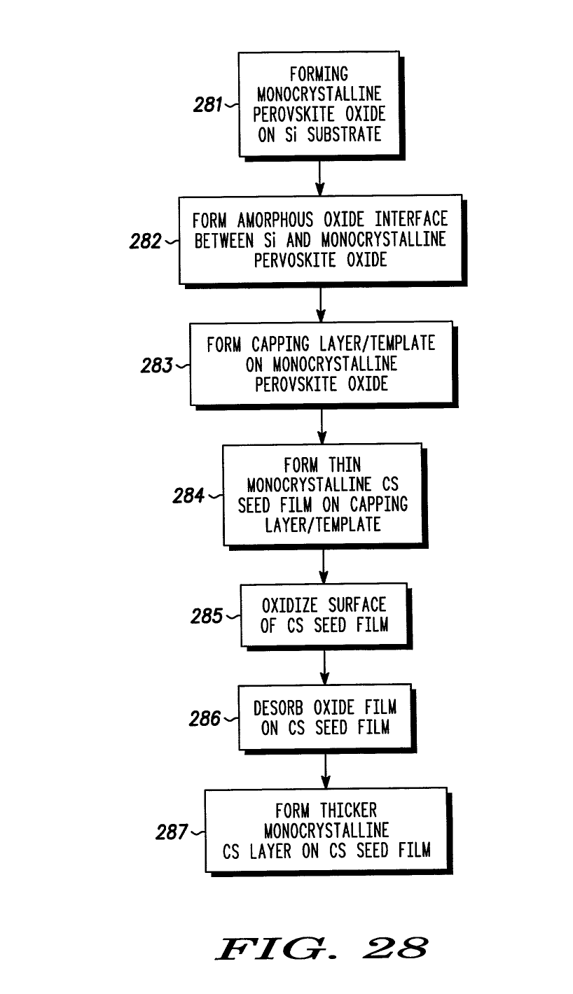

This basic process scheme for forming composite semiconductor structure 267 is summarized in FIG. 28 as steps 281-287, respectively.

Optionally, prior to forming the compound semiconductor layer 266 as shown in FIG. 27, the accommodating buffer layer 24 and the compound semiconductor seed film (261 or 264) can be subjected to an anneal process sufficient to reduce crystal defects in seed film. This anneal also optionally can be performed at a temperature effective to transform the accommodating buffer layer 24 from a monocrystalline state to an amorphous state (not shown), such that the combination of the amorphous oxide layer 28 and the amorphized accommodating buffer layer 24 form a single amorphous oxide layer similar to that described relative to FIG. 3.

Also, according to another optional embodiment of the invention, the removal of the contaminated surface region 262 could be delayed until the compound semiconductor film 261 itself acquires a thickness suitable for formation of devices therein, and thereby making it possible to eliminate the regrowth step. Although with this optional strategy, there may be an increased risk of the surface contaminants getting incorporated into the bulk of the thicker compound semiconductor material layer as undesired dopants where devices might be formed.

### EXAMPLE 8

Referring now to FIGS. 29-31, in this embodiment the process described in Example 7 is modified such that the surface region 262 of the monocrystalline compound semiconductor film 261 which is contaminated with perovskite oxide metal(s) is instead removed by an etch back procedure, and then a thicker monocrystalline semiconductor layer 269 is epitaxially grown on the remaining monocrystalline compound semiconductor film 268.

In this example, the intermediate structure shown in FIG. 29 is the same construction as that shown in FIG. 24, and discussed above. Again, metal contaminants originating from perovskite oxide film 24 become present at the surface region 262 of seed film 261 due to the surface segregation phenomenon described above.

Referring to FIG. 30, part of the thickness of the monocrystalline compound semiconductor film 261, including the surface region 262, has been uniformly removed by an anisotropic etch process, leaving a thinner monocrystalline compound semiconductor film 268 having a significantly reduced level of metal contaminants originating from the perovskite oxide film 24 as compared to that of the original seed film 261. The anisotropic etch back can be performed using wet or dry anisotropic etching systems.

For instance, the workpiece can be removed from the growth chamber after forming film 261 and placed inside an etch chamber. A suitable wet etchant will remove the compound semiconductor material and contaminant metals present in the surface region 262 of the seed film 261. Moreover, the etchant should be anisotropic in nature to help ensure a uniform thickness of the seed film 261 is removed, leaving a uniform flat surface for regrowth.

For instance, where the seed film 261 comprises a Group III-V compound semiconductor material, such as GaAs, and the perovskite oxide film comprises strontium titanate, the use of etchant solution formulated as phosphoric acid:hydrogen peroxide:water in a 3:1:50 (in volume percentages) mixture, has been demonstrated to remove gallium arsenide and strontium and/or titanium contaminants from the surface of the thin gallium arsenide film. The etch also works by oxidizing the GaAs surface and removing the oxide, but by dissolving rather than desorption. The hydrogen peroxide is an oxidizing agent, and the phosphoric acid and water help dissolve the oxide formed. Thin gallium arsenide films also can be selectively wet etched with 1:8:160 (by volume) of sulfuric acid:hydrogen peroxide:water. Indium phosphide can be selectively wet etched in this embodiment, for example, with 1:1:15 (by volume) phosphoric acid:hydrogen peroxide:water, 1:1:1 hydrochloric acid:phosphoric acid:water, or 8:1 (by volume) phosphoric acid:water. GaInP can be wet etched, for example, using 3:1 (by volume) hydrochloric acid:phosphoric acid.

Alternatively, a suitable anisotropic dry etchant can be used to remove the compound semiconductor material and contaminant metals present in the surface region 262 of the seed film 261. For instance, reactive ion etching (RIE) is particularly useful.

Where the seed film 261 comprises a Group III-V compound semiconductor material, such as GaAs, the entire structure can be placed in a reaction chamber of a reactive ion etching apparatus. A gallium arsenide film 261 can be anisotropically dry etched effective to remove the contaminated surface region 262 using reactive gases such as boron trichloride combined with sulfur hexafluoride, carbon tetrachloride, carbon dichlorodifluoride, or other conventionally used chlorofluorocarbons. An indium phosphide film 261 can be anisotropically plasma etched effective to remove the contaminated surface region 262 using reactive gases such as boron trichloride combined with an inert gas such as nitrogen, or other suitable or conventional plasma etching gas systems used on this material.

Ion milling is not preferred as the dry etching method due to the surface damage caused that is associated with that technique.

As shown in FIG. 31, after removing the contaminated surface region 262 from the seed film 261 by anisotropic etch back, the workpiece is placed in a growth chamber in which compound semiconductor device layer 269 is epitaxially grown on the remaining seed film 268 to provide device structure 270. The thicknesses of the monocrystalline compound semiconductor film, before and after the etch back procedure, can be generally similar to the respective ranges described above for the alternative surface treatment of this film by oxidation and desorption.

Experimental studies were performed on device structures 270 constructed similar to that described in Example 1 except that a 2000 Angstroms thick gallium arsenide seed film was first formed on the template layer, and the seed film was wet etched with a 3:1:50 formulation of phosphoric acid:hydrogen peroxide:water until the gallium arsenide seed film was reduced to a thickness of about 600 Angstroms. Thereafter, a thicker gallium arsenide layer having a thickness of about 2250 Angstroms was regrown on the etched seed film. Several samples of structures were prepared in this manner, and were compared to structures prepared according to Example 1 made without the etch back and regrowth procedures according to this embodiment. The samples that had been etched back and regrown according to this embodiment displayed significant increases in mobility, as measured in terms of cm²/Vs, including one increase greater than ten-fold in magnitude (at room temperature), as compared to the samples not treated in this manner. In addition, there was no photoluminescence shown in the samples prior to the etch back and regrowth treatment, while etched and regrown samples were found to show photoluminescence.

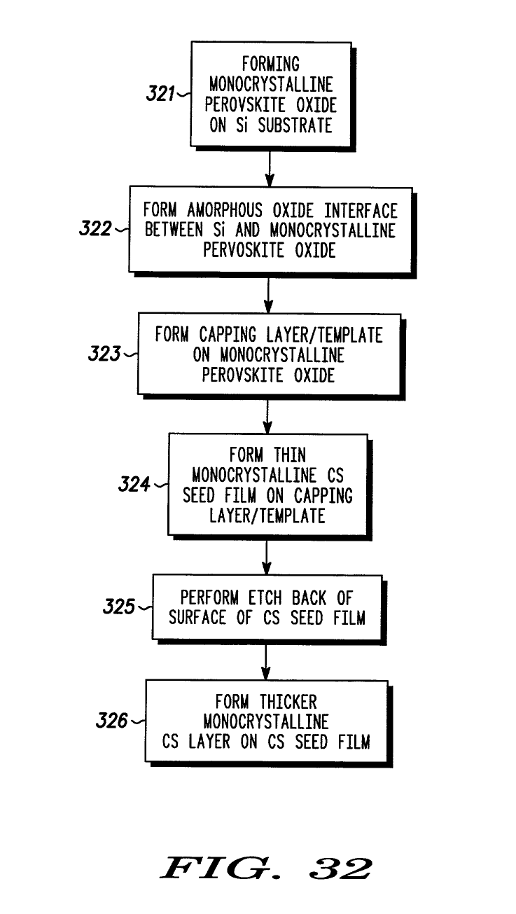

This basic process scheme for forming composite semiconductor structure 270 is summarized in FIG. 32 as steps 321-326, respectively.

In the foregoing specification, the invention has been described with reference to specific embodiments. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of present invention.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential features or elements of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

We claim:

1. A process for fabricating a semiconductor structure, comprising the steps of:
providing a monocrystalline silicon substrate;
depositing a monocrystalline perovskite oxide film overlying the monocrystalline silicon substrate, the monocrystalline perovskite oxide film having a thickness less than a thickness of the material that would result in strain-induced defects;
forming an amorphous oxide interface layer containing at least silicon and oxygen at an interface between the monocrystalline perovskite oxide film and the monocrystalline silicon substrate;
forming a monocrystalline compound semiconductor film overlying the monocrystalline perovskite oxide film, said monocrystalline compound semiconductor film having metal components from the perovskite oxide film in at least a first surface region thereof;
removing at least a portion of the metal components in the first surface region from the monocrystalline compound semiconductor film; and
epitaxially forming a monocrystalline compound semiconductor layer on the monocrystalline compound semiconductor film, where the monocrystalline compound semiconductor layer has a thickness greater than that of the monocrystalline compound semiconductor film.

2. The process accordance with claim 1, including eliminating a type of metal component present in the first surface region that also is present in said monocrystalline perovskite oxide film by removing the first surface region effective to expose a second surface region of the monocrystalline compound semiconductor film.

3. The process accordance with claim 2, wherein the second surface region of the monocrystalline compound semiconductor film contains a smaller amount of said metallic component than said first surface region.

4. The process accordance with claim 1, wherein the forming of the monocrystalline compound semiconductor film comprises depositing at least first and second Group III-V components, and the removing of at least a portion of the metal components comprises oxidizing said first surface region effective to oxidize the Group III-V components in the first surface region, and then desorbing the oxidized Group III-V components to eliminate the first surface region.

5. The process in accordance with claim 4, where said oxidizing comprises exposing the first surface region to an oxidizing atmosphere containing oxygen radicals.

6. The process in accordance with claim 4, where said oxidizing comprises exposing the first surface region to an oxidizing atmosphere containing ozone.

7. The process in accordance with claim 4, where said desorbing comprises heating the first surface region to a temperature effective to volatize the oxidized Group III-V components.

8. The process in accordance with claim 7, wherein said heating comprises heating the first surface region by a process selected from laser heating, e-beam heating, and thermal heating.

9. The process in accordance with claim 4, where said Group III-V components comprise gallium and arsenide, and said desorbing comprises heating the first surface region to a temperature of about 650° C. to about 700° C.

10. The process in accordance with claim 9, wherein, during said desorbing, an electron beam comprised of elemental arsenic is impinged upon the first surface region.

11. The process in accordance with claim 1, wherein the removing of at least a portion of the metal components of the first surface region comprises performing anisotropic etching.

12. The process in accordance with claim 11, wherein said anisotropic etching comprises anisotropic wet etching

13. The process in accordance with claim 11, wherein said anisotropic etching comprises contacting said first surface region with a wet etchant solution comprising a phosphoric acid, hydrogen peroxide, and water.

14. The process in accordance with claim 11, wherein said anisotropic etching comprises anisotropic dry etching.

15. The process in accordance with claim 11, wherein said anisotropic etching comprises reactive ion etching.

16. The process in accordance with claim 1, wherein said step of forming the monocrystalline compound semiconductor film comprises forming a thickness thereof between about 10 Angstroms to about 2,500 Angstroms.

17. The process in accordance with claim 1, wherein said step of forming the monocrystalline compound semiconductor film comprises forming a thickness thereof between about 50 Angstroms to about 600 Angstroms.

18. The process in accordance with claim 1, wherein said step of epitaxially forming the monocrystalline compound semiconductor layer comprising forming a thickness thereof greater than about 1,000 Angstroms.

19. The process in accordance with claim 1, wherein said step of forming the monocrystalline compound semiconductor film comprises epitaxially depositing a compound semiconductor film comprising a Group III-V semiconductor compound, and said step of epitaxially forming the monocrystalline compound semiconductor layer comprises depositing the same Group III-V semiconductor compound as that used in forming the compound semiconductor film.

20. The process in accordance with claim 1, wherein, after said depositing of said monocrystalline perovskite oxide film and before forming said monocrystalline compound semiconductor seed film,
depositing, on the monocrystalline perovskite oxide film, at least one monolayer comprising a metallic component identical in type to one present in said monocrystalline perovskite oxide film; and
depositing, on the at least one monolayer, at least one monolayer comprising a Group III or Group V element material identical to a Group III or Group V element material to be provided in the monocrystalline semiconductor seed film.

21. A semiconductor device, comprising:
a monocrystalline silicon substrate having a surface;
an amorphous oxide material layer overlying the surface of the monocrystalline silicon substrate;
a monocrystalline perovskite oxide material overlying the amorphous oxide material layer, said monocrystalline perovskite oxide material including first and second metal components;
a monocrystalline compound semiconductor film overlying the monocrystalline perovskite oxide material, said monocrystalline compound semiconductor film having a predetermined thickness and a cleaned surface region, and wherein said monocrystalline compound semiconductor film has a substantially reduced content of metal components of types identical said first and second metal components at said cleaned surface region thereof by removal of an original surface region of the monocrystalline compound semiconductor film effective to expose the cleaned surface region; and
a monocrystalline compound semiconductor layer overlying the cleaned surface region of the monocrystalline compound semiconductor film, said monocrystalline compound semiconductor layer having a thickness larger than the predetermined thickness of the monocrystalline compound semiconductor film.

22. The device in accordance with claim 21, wherein the monocrystalline compound semiconductor film has a thickness between about 10 Angstroms about 2,500 Angstroms.

23. The device in accordance with claim 21, wherein said monocrystalline compound semiconductor film comprises at least first and second Group III-V components.

24. The device in accordance with claim 21, wherein the monocrystalline compound semiconductor layer and the monocrystalline compound semiconductor film comprise the same type of Group III-V compound semiconductor material.

25. The device in accordance with claim 21, wherein the monocrystalline compound semiconductor layer and the monocrystalline compound semiconductor film comprise the same type of Group III-V compound semiconductor material selected from the group consisting of gallium arsenide, indium phosphide, gallium indium arsenide, gallium aluminum arsenide, and gallium indium arsenide.

26. The device in accordance with claim 21, wherein the monocrystalline perovskite oxide film is selected from the group consisting of strontium titanate, barium strontium titanate, barium titanate, strontium zirconate, barium zirconate, strontium hafnate, barium hafnate, and barium stannate.

27. The device in accordance with claim 21, wherein the monocrystalline compound semiconductor film has a thickness between about 50 Angstroms to about 600 Angstroms, and the monocrystalline compound semiconductor layer has a thickness of about 1,000 Angstroms or greater.

28. The device in accordance with claim 21, wherein the monocrystalline compound semiconductor film has a thickness between about 75 Angstroms to about 125 Angstroms, and the monocrystalline compound semiconductor layer has a thickness of about 10,000 Angstroms or greater.
